(19) United States
(12) Patent Application Publication
(10) Pub. No.: US 2012/0135237 A1
(43) Pub. Date: May 31, 2012

(54) SELF-ASSEMBLY OF LITHOGRAPHICALLY PATTERNED POLYHEDRAL NANOSTRUCTURES AND FORMATION OF CURVING NANOSTRUCTURES

(75) Inventors: David H. Gracias, Baltimore, MD (US); Jeong-Hyun Cho, Los Alamos, NM (US)

(73) Assignee: THE JOHNS HOPKINS UNIVERSITY, Baltimore, MD (US)

(21) Appl. No.: 13/266,558

(22) PCT Filed: Apr. 28, 2010
(86) PCT No.: PCT/US10/32696

§ 371 Date: Jan. 18, 2012

Related U.S. Application Data
(60) Provisional application No. 61/173,427, filed on Apr. 28, 2009.

(51) Int. Cl. B32B 5/16; H01L 21/302; G03F 7/20; B29C 59/02; B82Y 40/00; B82Y 99/00

(52) U.S. Cl. 428/402; 430/296; 264/293; 216/2; 977/700; 977/901; 977/887; 977/888

(57) ABSTRACT

The self-assembly of polyhedral nanostructures having at least one dimension of about 100 nm to about 900 nm with electron-beam lithographically patterned surfaces is provided. The presently disclosed three-dimensional nanostructures spontaneous assemble from two-dimensional, tethered panels during plasma or wet chemical etching of the underlying silicon substrate. Any desired surface pattern with a width as small as fifteen nanometers can be precisely defined in all three dimensions. The formation of curving, continuous nanostructures using extrinsic stress also is disclosed.

### CROSS-REFERENCE TO RELATED APPLICATIONS

This application claims the benefit of U.S. Provisional Application No. 61/173,427, filed Apr. 28, 2009, which is incorporated herein by reference in its entirety.

### FEDERALLY SPONSORED RESEARCH OR DEVELOPMENT

This invention was made in part with United States Government support under 1-DP2-OD004346-01 awarded by the National Institutes of Health (NIH) and Grant No. 0854881 awarded by the National Science Foundation (NSF). The U.S. Government has certain rights in the invention.

### BACKGROUND

The inability to construct three-dimensional (3D) nanostructures having any desired surface pattern is a major hindrance in current nanoscale science and engineering. Although it has been demonstrated that objects can be patterned in three dimensions on the macroscale, it has proven to be extremely challenging to construct nanostructures that are spatially patterned in all three dimensions. Although many nanostructures, such as nanowires, nanotubes, and nanoparticles, have been developed, such nanostructures can be fabricated with only limited surface patterning, for example, ring patterns on nanowires. See Qin, L., et al., Science 309, 113 (2005).

Many silicon-based lithographic and machining techniques, such as electron-beam (e-beam) lithography, imprint lithography, and focused ion-beam methods, provide for patterning down to the nanoscale. These projection techniques, however, can be implemented in an inherently two-dimensional (2D) manner only and it can be difficult to fabricate 3D structures using conventional silicon-based fabrication processes. See, e.g., Madou, M., Fundamentals of Microfabrication (CRC, Boca Raton, Fla., 1997). Despite this restriction, lithographic patterning is extremely precise in 2D. Because considerable infrastructure for lithographic fabrication processes already exists, this engineering paradigm is unlikely to be abandoned.

A 3D nanoscale structure, however, offers several potential advantages over 2D structures in biomedical applications, including, but not limited to, a larger external surface area to volume ratio, which maximizes interactions with the surrounding medium and provides sufficient surface area to accommodate or attach diagnostic or delivery modules; a finite volume allowing encapsulation of therapeutic agents, biological materials, and other materials, such as gels and polymers; and an ability to manipulate its geometry to reduce the chances of the device being undesirable lodged in an organism, e.g., a subject's body.

Additionally, with regard to the development of curving, continuous nanostructures, many thin films develop high residual stress during deposition. These stresses develop due to grain boundaries, dislocations, voids, and impurities within the film itself, or interfacial factors, such as a lattice mismatch, difference in thermal expansion, or adsorption. See G. G. Stoney, Pro. R. Soc. London A 82:172 (1909); W. D. Nix, Metall. Mater. Trans. A 20:2217 (1989); L. B. Freund, S. Suresh, Thin Film Materials Stress, Defect Formation and Surface Evolution; Cambridge University Press, New York (2009); R. Koch, J. Phys. Condens. Matter 6, 9519 (1994). It is known that these intrinsic stresses can cause the spontaneous curving of substrates on which they are deposited. See R. W. Hoffman, Thin Solid Films 34:185 (1976). If the substrate is much thicker than the stressed thin film, the substrate curves with a large radius of curvature. See M. Ohring, Materials Science of Thin Films, Academic Press, San Diego, pp. 711-781 (2002).

In contrast, when the stressed thin film is deposited atop or below another thin film and the films are released from the substrate, it will spontaneously curve with a micro or nanoscale radii of curvature. See C. L. Chua, et al., J. Microelectromech. Syst. 12:989 (2003); Y. V. Nastaushev, et al., Nanotechnology 16:908 (2005); O. G. Schmidt, et al., Adv. Mater. 13:756 (2001); M. Huang, et al., Adv. Mater. 17:2860 (2005); V. Y. Prinz, et al., Physica E 6:828 (2000); O. G. Schmidt, K. Eberl, Nature 410:168 (2001); Y. Mei, et al., ACS Nano 3:1663 (2009). It is challenging, however, to achieve the high intrinsic stress magnitudes needed to enable assembly with small nanoscale radii of curvature; typically, heteroepitaxial deposition at elevated temperatures is required, see V. Y. Prinz, et al., Physica E 6:828 (2000); O. G. Schmidt, K. Eberl, Nature 410:168 (2001); Y. Mei, et al., ACS Nano 3:1663 (2009), which limits the types of devices and structures that can be assembled.

### SUMMARY

In some aspects, the presently disclosed subject matter provides a method for fabricating polyhedral nanostructures that are patterned in three dimensions. The particular patterns on the surfaces of components comprising such nanostructures can direct self-assembly to form three-dimensional nanostructures. In particular aspects, the presently disclosed subject matter demonstrates that electron-beam (e-beam) or imprint lithography can be used to precisely pattern two-dimensional nanoscale panels to have binding sites, e.g., hinges, on one or more edges available for attaching to and interconnecting with other nanoscale panels. The interconnected nanoscale panels have the property of self-assembly and, upon self assembly, form a polyhedral nanoscale structure.

In another aspect, the presently disclosed subject matter provides a method for fabricating curving, continuous hingeless nanostructures, which are formed as a result of extrinsic stresses that develop due to grain coalescence in thin films upon heating after deposition. The presently disclosed methods require only thermal evaporation and low temperature processing and the stress required for self-assembly can be controlled to occur only when desired. In such aspects, the layers also can be patterned with conventional lithographic processing, including electron-beam lithography.

Certain aspects of the presently disclosed subject matter having been stated hereinabove, which are addressed in whole or in part by the presently disclosed subject matter, other aspects will become evident as the description proceeds when taken in connection with the accompanying Examples and Drawings as best described herein below.

### BRIEF DESCRIPTION OF THE DRAWINGS

Having thus described the presently disclosed subject matter in general terms, reference will now be made to the accompanying Drawings, which are not necessarily drawn to scale, and wherein:

FIGS. 1a and 1b are schematic representations of (a) nanoparticles known in the art and (b) representative embodiments of the presently disclosed nanostructures, where nanostructures with any arbitrary defined pattern on polyhedral and curved structures; patterns are precisely enabled in all three dimensions;

FIGS. 2a and 2b are schematic representations of the presently disclosed curving hingeless structures and rotating hinged structures: (a) schematic representation of forming simultaneously curved and patterned hingeless nanostructures; and (b) schematic representation of forming patterned hinged polyhedral structures;

FIGS. 3a-3c are schematic diagrams depicting the presently disclosed self-assembly process: (a) patterned panels with binding sites that interact without constraints are unlikely to self-assemble into cubes; (b) joining panels to form nets limits the possible interactions and allows them to assemble to form a nanocube; and (c) self-assembly is driven by the reflow of tin (Sn) within the hinges of the net; the panel angular orientation needed for self-assembly is derived from the force that is generated when the reflowed hinges minimize their surface area;

FIG. 4 is a schematic diagram of the presently disclosed patterning and self-assembly process. From left to right: two-dimensional (2D) templates with panels and hinges were fabricated using two steps of electron-beam (e-beam) lithography; these templates spontaneously assemble to form cubic structures during plasma etching of the underlying silicon substrate;

FIGS. 5a-5c are scanning electron microscopy (SEM) images showing results of experiments investigating tin (Sn) reflow in a plasma etcher: (a) a 50-nm thick Sn film evaporated on a silicon wafer prior to reflow; (b) the Sn film after exposure to an argon (Ar) plasma with a 10-sccm flow rate for two minutes; no reflow or significant change was observed; and (c) the Sn film after exposure to an O₂/CF₄ plasma with a 3.6- and 12-sccm flow rate of O₂ and CF₄, respectively, for two minutes; significant reflow was observed. Scale bars: 200 nm;

FIGS. 6a and 6b are energy dispersive spectroscopy (EDS) characterization of 50-nm thick Sn films deposited on patterned 10-micron and 200-nm thick square patterns of Ni on Si substrates, before and after etching with CF₄/O₂ plasma: (a) after plasma etching with a 3.6- and 12-sccm flow rate of O₂ and CF₄, respectively, for two minutes, approximately 12% atomic concentration of fluorine (F) was observed within the reflowed Sn; (b) zoomed in EDS spectrum within the range of 0.1-1.1 KeV;

FIGS. 7a-71 are results of experiments demonstrating that the orientation angle can be controlled by varying the ratio of O₂ to CF₄. SEM images of Sn thin films on a silicon wafer and 500-nm sized 2D nets before and after plasma etching: (a-c) images of a Sn thin film and 2D nets before plasma etching. (a) 50-nm thick Sn on a silicon wafer; (b, c) progressively zoomed-in images of Ni panels with Sn hinges; (d-f) images of the Sn film and 2D nets after plasma etching with a 0.2- and 12-sccm flow rate of O₂ and CF₄, respectively. (d) the Sn film shows some grain coalescence (of grains less than 50 nm in size), but no significant reflow of large grains; (e, f) progressively zoomed-in images showing that the 2D nets assemble with angles of approximately 45° under these conditions; (g-i) SEM images of the Sn film and 2D nets after plasma etching with a 3.6- and 12-sccm flow rate of O₂ and CF₄, respectively; (g) the Sn film shows considerable reflow; (h) progressively zoomed-in images showing that the 2D nets assemble with angles of approximately 90° under these conditions. It should be noted that the assembly process is parallel and (i) the particles have the letters JHU patterned with line widths as small as 15 nm. Scale bars: 200 nm;

FIG. 8A shows representative results of the presently disclosed methods. From left to right: scanning electron microscopy (SEM) images, with increasing magnification, showing 500-nm sized 2D, e-beam patterned templates, which self-assembled into the cubic structures shown. In these examples, the structures have the letters JHU patterned on each face; the line width of the pattern is about 15 nm;

FIG. 8B from left to right shows SEM images featuring correctly assembled 200-nm and 900-nm sized cubes with a square patterned on each face; fold angles less than about 90 degrees were observed at very low or high O₂ gas partial pressure; defects in lithographic alignment resulted in missing hinges, which prevented the respective panel from rotating;

FIG. 8C is SEM images showing results obtained with 100-nm sized panels. From left to right: progressively zoomed 2D templates; also shown is a self-assembled structure with hinge angles less than 90 degrees and those with 90 degree fold angles. Scale bars: 100 nm;

FIGS. 9a-9d are SEM images of 100-nm scale cubic structures before and after self-assembly: (a) lithographically patterned Ni panels whose surfaces were patterned with 30-nm squares; (b) lithographically patterned Sn hinges on Ni panels; (c) a magnified image of the hinges and panels; and (d) 100-nm scale cubic structures after self-assembly. Scale bars: 100 nm;

FIGS. 10a-10c are representative embodiments of nanopyramids formed by the presently disclosed self-folding process;

FIGS. 11a-11c are SEM images of 500-nm scale cubic structures patterned with dissimilar materials. The structures have 20-nm thick curvilinear patterns of Au defined precisely with the letters J and U with 50-nm line widths on the outer faces of Ni. The SEM images were captured using a back scatter detector, which is sensitive to the atomic mass; hence the Au appears brighter than Ni: (a) SEM image of a patterned cubic structure of Au on Ni; (b) in addition to the pattern of Au on Ni, the structure also has 100-nm square holes patterned within each face; and (c) SEM image showing the parallel nature of the assembly with yields of approximately 30%. Scale bars: 100 nm;

FIGS. 12a-12c are SEM images of five- and six-faced cubes with patterns: (a) metallic six-faced cube with JHU inscribed on each face; and (b, c) alumina (Al₂O₃) cubes with gold patterns on each face;

FIG. 13 is SEM images of grain coalescence in tin (Sn) thin films deposited on a silicon substrate with increasing plasma processing time. The plasma power was 25 W with gas flow rates of O₂=3.6 and CF₄=12 sccm;

FIGS. 14a-14d are schematic diagrams and scanning electron microscopy (SEM) images showing the origin of the high extrinsic stress observed within the Sn film that causes Ni/Sn bilayers to curl with nanoscale radii of curvature: (a) the induction of grain coalescence in Sn films during plasma processing causes a large extrinsic stress; (b) SEM images of Sn thin films deposited on bare Si before and after grain coalescence. Grain coalescence resulted in spontaneous curving of the released edges of the film due to the stress gradient generated; and (c) when deposited atop a Ni film, the stress generated within the Sn thin film due to grain coalescence was large enough to cause the Sn/Ni bilayer to curl; and (d) SEM image of Ni/Sn bilayer curving into a nanoscale tubular structure with 20-nm radii of curvature (left panel). Also shown is a nanoscale ring (right panel);

FIGS. 15a-15c are results from a control experiment with a polymeric sacrificial layer demonstrating that the release of the structure from the underlying substrate and the self-assembly steps can be decoupled: (a) schematic showing the deposition of a Ni/Sn bilayer atop a polyvinyl alcohol (PVA) sacrificial layer (left). On dissolution of this sacrificial layer no curvature was observed in the released structure (middle top). Curvature was triggered only by inducing grain coalescence, which could be achieved in a subsequent step (right). SEM images of a square patterned Ni 5 nm/Sn 5 nm film: (b) after release from the Si substrate showing no curvature and (c) after Sn grain coalescence was induced;

FIGS. 16a-16b are control experiments: (a) when bare Ni cantilevers were patterned and the underlying Si layer was plasma etched; (b) no curving was observed. This experiment shows that neither intrinsic nor extrinsic stresses in Ni could cause curvature;

FIGS. 17a-17c are experimental results showing the variation of the radii of curvature with the cantilever geometry: (a) variation in thickness (L=300 nm and W=50 nm); (b) variation in length (W=50 nm); and (c) variation in width (L=1000 nm);

FIGS. 18a-18g are SEM images of the variation of curvature with varying widths showing that nanostructures with both homogeneous and varying radii of curvature can be self-assembled: (a) SEM image of the curving of cantilevers with different widths (50 nm, 100 nm, 200 nm, and 300 nm). All cantilevers have the same L=1 μm and thickness (Ni 10/Sn 2.5 nm). Cantilevers with the same width show the same radii of curvature, while those of larger widths have larger radii of curvature. This result highlights the reproducibility of the self-assembly process; (b) SEM image of cantilevers with varying width along the length of the cantilever (i.e. W₁<W₂): (c) a cantilever with varying width curved with varying radii of curvature due to a varying area moment of inertia, resulting in the formation of a nanospiral; (d) Nanoscale three-fingered talon shaped structures before and after coalescence; (e,f) square and rectangular patterns (Sn 5 nm/Ni 5 nm) before and after coalescence developed bending forces F_{V} and F_{H} of different magnitudes and directions; (g) tilted zoomed-in image of the nanoscroll shown in (f);

FIGS. 19a-19d are SEM images for the characterization of radii of curvature as a function of width: (a) as deposited and patterned cantilevers with varying width W1 and W2; (b) after grain coalescence was induced in cantilevers with Ni=5 nm, Sn=5 nm, W1=200 nm, and W2=400 nm, different depths of curvature Da at aa′ and Db at bb′ were observed due to different area moment of inertia. During grain coalescence and etching of the Si substrate, the Ni/Sn beam starts to curve first along the y-axis with radii of curvature R1 (cross-sectional view at aa′) and R2 (at bb′). R1 and R2 are of almost the same magnitude. The depth of the curvature Da at aa′, however, is smaller than Db at bb′, because the width of the cantilever at aa′ is smaller than bb′. The large Db implies a large area moment of inertia of the cantilever beam at bb′; (c) as etching progresses, curving begins along the x-axis (in addition to the earlier curving along the y-axis). Since the rigidity of the cantilever beam increases with increasing moment of inertia, as described by Euler-Bernoulli beam theory, see Pilkey, W. D. Analysis and Design of Elastic Beams (John Wiley & Sons, New York, (2002)), they curve to a lesser extent (with larger R values). Therefore, R along the x-axis could be varied by varying W. Based on this concept, the radii of curvature were controlled and 3D nanospirals, which have a non-uniform radius of curvature along their length, were constructed. Further, W1=100 nm widths were designed at the one end of the cantilevers and gradually increased the width to W2=200 nm at the other end. These cantilevers had a thickness of Ni=5 nm, Sn=10 nm. After Sn grain coalescence was induced, the cantilever curved into a spiral shape with inner and outer radii of curvature of 70 and 300 nm, respectively; (d) Spirals with larger radii using wider widths W1=150 nm and W2=300 nm also were fabricated;

FIGS. 20a-20f demonstrate the presently disclosed surface patterning materials versatility (a-e) and the parallel nature of the assembly process (O, SEM images of single rolled nanotubes without patterning (a) and with patterning (b) of pores; (c-e) nanostructures, such as rings and scrolls with the letters JHU and NANOJHU patterns on them; (f) curving nanostructures composed of a dielectric material, e.g., alumina (Al₂O₃ 6 nm/Sn 5 nm); and

FIG. 21a-21d are SEM images of as deposited and e-beam patterned X/Sn structures. Images in the right column are zoomed-in images of the sections indicated by the dotted line in the left column. (a) 2D Cantilever patterns with Ni 10 nm/Sn 10 nm on a Si substrate; (b) patterns (Ni 5 nm/Sn 5 nm) with nanopores. After grain coalescence, single rolled nanotubes could be formed (FIG. 20b); (c) patterns (Ni 10 nm/Sn 10 nm) with the letters JHU for the FIG. 20c; (d) patterns (Ni 5 nm/Sn 5 nm) with the letters NANOJHU. After grain coalescence, these curved to form nanoscrolls (FIG. 20d-e).

### DETAILED DESCRIPTION

The presently disclosed subject matter now will be described more fully hereinafter with reference to the accompanying Drawings, in which some, but not all embodiments of the inventions are shown. Like numbers refer to like elements throughout. The presently disclosed subject matter may be embodied in many different forms and should not be construed as limited to the embodiments set forth herein; rather, these embodiments are provided so that this disclosure will satisfy applicable legal requirements. Indeed, many modifications and other embodiments of the presently disclosed subject matter set forth herein will come to mind to one skilled in the art to which the presently disclosed subject matter pertains having the benefit of the teachings presented in the foregoing descriptions and the associated Drawings. Therefore, it is to be understood that the presently disclosed subject matter is not to be limited to the specific embodiments disclosed and that modifications and other embodiments are intended to be included within the scope of the appended claims.

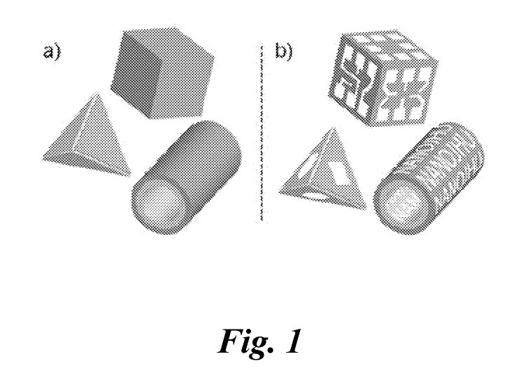

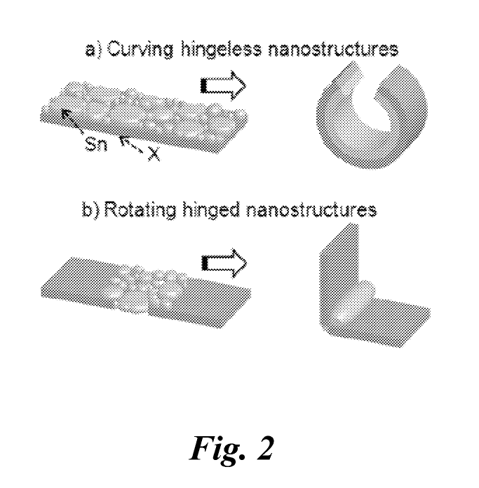

As provided in more detail herein below, the presently disclosed subject matter provides, in some embodiments, methods for fabricating lithographically patterned polyhedral nanostructures. In other embodiments, the presently disclosed subject matter provides methods for forming curving, continuous nanostructures. As shown in FIGS. 1a and 1b, in contrast to nanostructures known in the art that do not include nanoscale features or patterns, see, e.g., FIG. 1a, the presently disclosed nanostructures, such as polyhedral nanostructures, including, but not limited to cubic and pyramidal nanostructures, and curved nanostructures, including, but not limited to tubes, rings, scrolls, spirals and talons, can be precisely patterned in all three dimensions and can have any arbitrary defined pattern. Further, as illustrated in FIGS. 2a and 2b, the presently disclosed nanostructures can include curving hingeless structures (FIG. 2a) and rotating hinged structures (FIG. 2b), which can be used to form three-dimensional polyhedral nanostructures.

### I. SELF-ASSEMBLY OF LITHOGRAPHICALLY PATTERNED POLYHEDRAL NANOSTRUCTURES

A. Background

The construction of three-dimensional (3D) objects having any desired surface pattern can be easily achieved in macroscale science and engineering. On the nanoscale, however, 3D fabrication using methods known in the art is restricted to objects having only limited surface patterning. For example, nanoparticles, such as nanowires and nanopolyhedra, are widely used in nanoscale science and engineering, but can be constructed with only limited surface patterning, e.g., ring patterns on nanowires. See Qin, L., et al., Science 309:113 (2005); Zhang, Z. and Glotzer, S. C. Nano Lett. 4:1407 (2004); Jackson, A. M., et al., Nat. Mater. 3:330 (2004); Srinivas, G. and Pitera, J. W. Nano Lett. 8:611 (2008).

Surface patterning can dramatically alter both the physical and chemical properties of an object. See, for example, Gleiche, M., et al., Nature 403:173 (2000); Curtis, A. S. G.; et al., Biophys. Chem. 94:275 (2001); Turner, S., et al., J. Vac. Sci. Technol., B 15:2848 (1997); Rastegar, A., et al., J. Appl. Phys. 89:960 (2001); Gay, G., et al., Nat. Phys. 2:262 (2006). It also is desirable to fabricate nanoparticles with any desired surface pattern to provide for the bottom-up assembly of artificial crystals and arrays. See Grzybowski, B. and Whitesides, G. M. Science 295:2418 (2002).

The inability to construct nanoparticles with any desired surface pattern arises from the fact that although nanoscale patterning techniques, such as electron beam lithography (EBL), see Beaumont, S. P., et al., Appl. Phys. Lett. 38:436 (1981), imprint lithography, see Chou, S. Y., et al., Science 272:85 (1996), and scanning probe lithography, see Liu, G.-Y., et al., Acc. Chem. Res. 33:457 (2000), are extremely precise, they can be implemented in an inherently two-dimensional (2D) manner only. As used herein, the term “two-dimensional,” which can be abbreviated as “2D,” refers to a figure, an object, or an area that has a height and a width, but no depth, and is therefore flat or planar. In contrast, the term “three-dimensional,” which can be abbreviated as “3D,” refers to a figure, an object, or an area that has a height, a width, and a depth.

Self-assembly, or the spontaneous assembly of interacting precursor templates to form well-ordered nanostructures, offers one possible solution to overcome the challenge of fabricating 3D objects having any desired surface pattern. Biological self-assembly, for example, provides for the construction of extremely complex three-dimensionally patterned nanoparticles, such as viruses. In biological assembly, several paradigms, such as steric constraints, hierarchical forces, and lock-and-key interactions, are used to direct the assembly by biasing specific outcomes. While some of these paradigms have been explored in meso- and microscale fabrication, see, e.g., Grzybowski and Whitesides, supra; Terfort, A., et al., Nature 386:162 (1997); Gracias, D. H., et al., Science 289:1170 (2000); Syms, R. R. A., et al., J. Microelectromech. Syst. 12:387 (2003); Leong, T. G., et al., Langmuir 23:8747 (2007), their potential for overcoming the significant challenge of three-dimensional nanoscale fabrication has yet to be realized.

The presently disclosed subject matter provides a self-assembly strategy that harnesses the strengths of conventional 2D nanoscale patterning techniques and additionally provides for the construction of stable 3D polyhedral nanostructures having specific and lithographically defined surface patterns.

B. Fabrication of Three Dimensional Nanostructures

The presently disclosed subject matter provides for the mass fabrication of untethered, free-standing, polyhedral nanostructures. Such nanostructures can be formed from the surface-tension-based self-assembly of two-dimensional precursor templates. As disclosed immediately hereinabove, the presently disclosed self-assembling nanostructures comprise hinges, which, in some embodiments, comprise fluidic locking hinges that are self-folding and, when actuated, fold to complete a polyhedral structure. In some embodiments, the polyhedral nanostructure can be sealed or otherwise enclosed by the interconnected nanoscale panels. Further, in some embodiments, the presently disclosed methods incorporate one or more sacrificial layers, which can be removed (e.g., developed) to completely release the three-dimensional nanostructures from a substrate upon which precursor templates of the nanostructures are formed.

By using electron-beam lithography in conjunction with the property of self-assembly, polyhedral structures having at least one dimension ranging from about 100 nm to about 900 nm can be fabricated. One of ordinary skill in the art would appreciate that structures patterned on two-dimensional substrates by any method, including, but not limited to, electron-beam lithography and imprint lithography, can be assembled into the presently disclosed three-dimensional nanostructures.

Further, one or more faces of the polyhedral nanostructure can be patterned with one or more nanoscale features having a line width as small as about fifteen nanometers. As used herein, the terms “patterned” and “nanopatterned,” and grammatical variants thereof, are used interchangeably and refer to any arbitrary two-dimensional pattern having nanoscale features, i.e., features having at least one dimension, e.g., a height, width, length, and/or depth, in a range from about one nm to about 999 nm, as those ranges are defined herein below. In some embodiments, the two-dimensional pattern can have a sub-nanometer dimension, i.e., a dimension having a range from about 0.1 nm to about 0.999 nm.

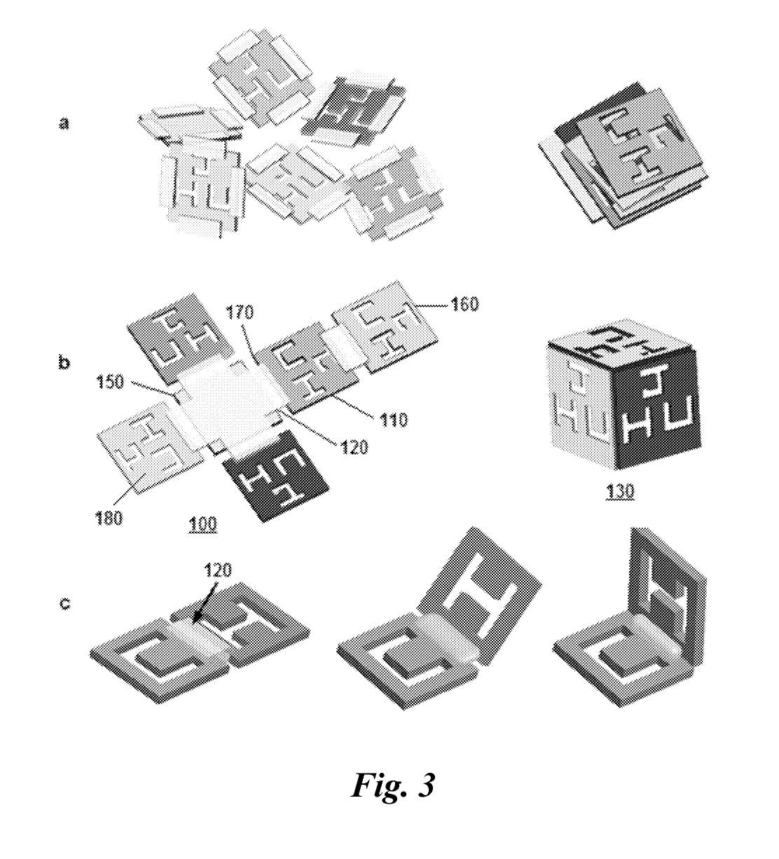

Referring now to FIG. 3a, when patterned nanoscale panels are allowed to interact without any additional constraints (see FIG. 3a (left panel)), a well-defined polyhedral structure is highly unlikely to form due to the large number of possible outcomes (see FIG. 3a (right panel)). On the other hand, the desired outcome can be influenced by joining one or more nanoscale panels, e.g., side panel 110, in 2D prior to assembly through one or more hinges 120 (FIG. 3b (left panel)). These panels can be oriented with any desired angle and subsequently fused to each other. Such embodiments include two-dimensional precursor templates 100 having a plurality of side panels 110 and hinges 120 (FIGS. 3b (left panel) and 3c), which can be precisely fabricated and assembled on a substrate (not shown), for example, a silicon (Si) wafer substrate. The precursor templates 100 can subsequently be released by etching, e.g., plasma etching or wet chemical etching, or dissolution of the substrate, whereby the precursor template self-assembles into a three-dimensional polyhedral nanostructure 130 (see FIG. 3b (right panel)).

In principle, using the presently disclosed methods and materials, any nanoscale, three-dimensional, polyhedral structure having precisely patterned faces can be constructed. In representative, non-limiting embodiments, the panels are square. One of ordinary skill in the art upon review of the presently disclosed subject matter would recognize that panels having other geometries are suitable for use with the presently disclosed methods and materials. For example, in another representative, non-limiting embodiment, the presently disclosed polyhedral nanostructures are nanopyramids.

Accordingly, the presently disclosed nanostructures can have any polyhedral shape. As used herein, the term “polyhedral” refers to of or relating to, or resembling a polyhedron. The term “polyhedron” refers to a three-dimensional object bounded by plane polygons or faces. The term “polygon” refers to a multisided geometric figure that is bound by many straight lines, including, but not limited to, a triangle, a square, a pentagon, a hexagon, a heptagon, an octagon, and the like. For example, the presently disclosed nanostructures, in some embodiments, can be a cube. A cube is a three-dimensional object bounded by six square faces or sides, with three sides meeting at each vertex, i.e., a corner. In other embodiments, the nanostructure can be a pyramid.

As used herein, the terms “nanoscale” or “nanostructure” refer to one or more structures that have at least one dimension, e.g., a height, width, length, and/or depth, in a range from about one nanometer (nm), i.e., 1×10⁻⁹ meters, to about 999 nm, including any integer value, and fractional values thereof, including about 1, 2, 5, 10, 20, 30, 40, 50, 60, 70, 80, 90, 100, 200, 500, 600, 700, 800, 900, 999 nm and the like). As used herein, the term “microscale” refers to one or more structures that have at least one dimension in a range from about one micrometer (μm), i.e., 1×10⁻⁶ meters, to about 999 μm.

Accordingly, the panels comprising the presently disclosed nanostructures can have a width ranging from about 100 nm to about 900 nm, in some embodiments from about 100 nm to about 500 nm; and a thickness from about 13 nm to about 120 nm, and in some embodiments, from about 13 nm to about 29 nm. The hinges comprising the presently disclosed nanostructures can have a length from about 80 nm to about 400 nm, in some embodiments, from about 80 nm to about 300 nm; a width ranging from about 48 nm to about 650 nm, in some embodiments, from about 48 nm to about 450 nm; and a thickness ranging from about 26 nm to about 130 nm, in some embodiments, from about 26 nm to about 47 nm. Further, the structures can have a gap between a panel and a hinge. The gap between panels can be about 10 nm to about 90 nm, and in some embodiments, between about 10 nm and about 50 nm (e.g., about 10% of the panel dimension).

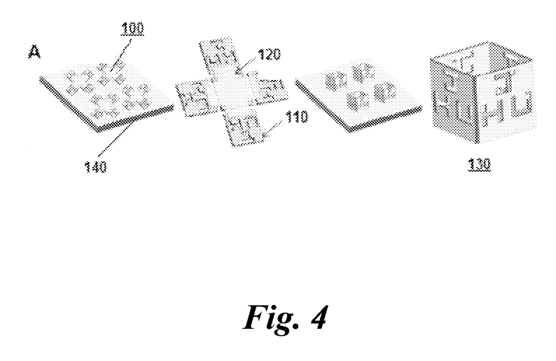

In representative, non-limiting embodiments, the presently disclosed subject matter demonstrates the self-assembly of lithographically patterned cubic nanoparticles. Referring now to FIG. 4, a schematic representation of a plurality of two-dimensional (2D) precursor templates 100 having a plurality of panels 110 and a plurality of hinges 120 can be prepared by using the presently disclosed two-step electron-beam (e-beam) lithography method. The plurality of precursor templates can be formed on substrate 140, for example, a silicon wafer (FIG. 4 (first panel)). In some embodiments, the plurality of templates comprises at least two panels 110, which are interconnected by a hinge 120. In some embodiments, the plurality of templates comprises a first central panel 150 (also referred to herein as a base panel) and at least four side panels 110. See FIG. 4 (second panel). Each side panel 110 is interconnected (or fused) to the base panel by a hinge 120.

In some embodiments, the plurality of templates comprises a second central panel 160 (also referred to herein as a top panel). See FIG. 3b (left panel). In such embodiments, each side panel 110 also is interconnected (or fused) to the base panel 150 by a hinge 120 and the top panel 160 is interconnected by a hinge 120 to at least one side panel 110 (on a side of said panel directly opposite to the side of the panel interconnected to base panel 150). See FIG. 3b (left panel). Each panel has an edge 170 and a face 180. The precursor templates 100 can spontaneously assemble to form cubic structures 130 during plasma etching of the underlying substrate 140. See FIG. 4 (third and fourth panels) and FIG. 3b (right panel).

The presently disclosed nanostructures can be fabricated from at least one material selected from the group consisting of a metal (meaning an element that is solid, has a metallic luster, is malleable and ductile, and conducts both heat and electricity), a polymer as that term is known in the art, a glass (meaning a brittle transparent solid with irregular atomic structure) a semiconductor (meaning an element, such as silicon, that is intermediate in electrical conductivity between conductors and insulators, through which conduction takes place by means of holes and electrons), and an insulator (meaning a material that is a poor conductor of heat energy and electricity). In some embodiments, the metal is selected from the group consisting of nickel and tin. In particular embodiments, the two-dimensional panels comprise silver. In some embodiments, the two-dimensional panels comprise a dielectric, such as Al₂O₃.

In some embodiments, a surface tension of the material comprising the one or more hinges provides the force necessary to fold the self-assembling 2D precursor templates into 3D nanostructures. The hinges can comprise any liquefiable or coalescing material. In particular embodiments, the hinge comprises a material, including but not limited to, a metal as defined hereinabove, a solder (meaning an alloy formulated to have a specific melting point for use in joining metals), a metallic (meaning a mixture containing two or more metallic elements or metallic and nonmetallic elements usually fused together or dissolving into each other when molten), a polymer, a glass that can be liquefied, and combinations thereof. In particular embodiments, the hinge comprises tin.

Each panel also includes a face, i.e., a planar two-dimensional surface, which can be patterned to include one or more nanoscale perforations or pores, for example, an array of nanoscale holes, and/or a three-dimensional pattern, for example, a line or curvilinear structure having a width, height, and length, or other patterned 3D structure. These perforations, pores, and three-dimensional patterns can be created photolithographically, electrolithographically, or by using electron-beam lithography. Such perforations or pores can have a dimension ranging from about 0.1 nm to about 100 nm and, in some embodiments, can have a dimension from about 10 nm to about 50 nm.

Thus, in some embodiments, the presently disclosed nanostructures comprise 2D photolithographically or electrolithographically nanopatterned precursors. The terms “photolithography,” “photo-lithography,” or “photolithographic process” refer to a lithographic technique in which precise patterns are created on a substrate, such as a metal or a resin, through the use of photographically-produced masks. Typically, a substrate is coated with a photoresist film, which is dried or hardened, and then exposed through irradiation by light, such as ultraviolet light, shining through the photomask. The unprotected areas then are removed, usually through etching, e.g., plasma etching or wet chemical etching, which leaves the desired patterns.

Further, the presently disclosed assembly process can be used with patterned, multilayer panels comprising dissimilar materials. For example, the panels can be patterned with gold (Au), for example, curvilinear Au features having line widths as small as 15 nm. In further embodiments, specific surface patterning of panels with Au or other materials provide for well-defined subsequent molecular patterning using self-assembled monolayers for targeted therapeutics. The presently structures also represent attractive building blocks for hierarchical self-assembly of nanostructured three-dimensional devices.

In some embodiments, the pattern on the presently disclosed nanoparticle can comprise an element of an electronic circuit or a complete electronic circuit including, but not limited to, a photovoltaic, an electrode element, a semiconductor component, a transistor, a diode, a photodiode, a sensor, an actuator, and a solar cell.

In yet other embodiments, the pattern on the presently disclosed nanoparticle included an optical element, including, but not limited to, a split ring resonator, a light emitting device, including a light emitting diode, a lasing device, a mirror, and a wave guiding device.

In other embodiments, the pattern on the presently disclosed nanoparticle can include a biomolecule, including, but not limited to, a protein, DNA, and a small organic molecule. As used herein, the term “small organic molecule” refers to organic compounds, whether naturally-occurring or artificially created (e.g., via chemical synthesis) that have relatively low molecular weight and that are not proteins, polypeptides, or nucleic acids. Typically, small molecules have a molecular weight of less than about 1500 g/mol. Also, small molecules typically have multiple carbon-carbon bonds. In yet other embodiments, the presently disclosed nanostructures can be associated with a biosensor.

More particularly, 2D nets having five or six square nanoscale panels and rectangular hinges can be prepared on silicon (Si) wafer substrates. The panels, e.g., one or more square panels, can include any desired linear or curved pattern. The pattern can be defined using a single step of lithography comprising, for example, a conventional polymethylmethacrylate resist and lift-off metallization. As used herein, the term “lift-off metallization” refers to a nanofabrication process with a sacrificial resist. In lift-off metallization, a sacrificial resist is deposited on a substrate, patterned by electron-beam lithography, and cured. After lithography, a metal is deposited on the resist pattern. The resist can be dissolved in an appropriate solvent and lifted off of the substrate. All metal that is not in contact with the substrate is removed along with the resist. The remaining metal forms the pattern on the substrate.

A second step of e-beam lithography can be used to pattern the hinges, which can be precisely aligned between adjacent panels. In some embodiments, the presently disclosed methods use nickel (Ni) to pattern the panels and tin (Sn) to pattern the hinges of the structures. The materials for patterning the panels and hinges, e.g., Ni and Sn, can be deposited by thermal evaporation.

After patterning, the precursor templates on the substrate can be loaded into an etcher, e.g., a planar etcher, for a period of time, for example, in the presence of carbon tetrachloride (CF₄) and oxygen (O₂) gases. The precursor templates undergo self assembly in the etcher as the hinges reflow due to heating, while the underlying Si substrate is being etched away. The etching of the underlying Si also releases the outer panels of the 2D net from the substrate, thereby allowing the precursor templates to self-assemble while still being attached to the substrate through the central panel. Without wishing to be bound to any one particular theory, it is believed that the torque needed to orient the panels is generated by the force that results from the minimization of surface energy of the reflowed hinges. See Syms, R. R. A., et al., J. Microelectromech. Syst. 12, 387 (2003); Leong, T. G., et al., Langmuir 23, 8747 (2007). After self-assembly, the polyhedral nanostructures can be released by additional or prolonged etching.

The released nanostructures fabricated by the presently disclosed methods are stable. For example, no obvious change in shape was observed on heating them to 500° C. in air at 1 atm. This feature is critical to the utility of these particles in real world applications and is in contrast with molecular self-assembling paradigms known in the art, see, for example, He, Y., et al., Nature 452:198 (2008), which generate 3D nanopolyhedra that would fall apart when placed in many nonaqueous solvents, in vacuum, or on heating. Representative fabrication processes and the resulting 3D polyhedral nanostructures are provided herein below in the Examples.

Self-assembly based on the minimization of surface energy is an attractive strategy to assemble nanostructures because these surface forces scale linearly with distance, as compared to gravitational forces that scale volumetrically. Therefore, it can be readily seen that at the nanoscale these surface forces are orders of magnitude larger than gravitational forces.

In nanoscale self-assembly, however, several challenges arise. For example, the challenge of patterning the 2D nets with critical dimensions as small as 10 nm was overcome using electron-beam lithography. When hinges having such small dimensions are defined, factors, such as grain size, wetting, and reflow, significantly affect the patterning and assembly process. To assess optimum grain size and wetting, a wide range of evaporation parameters and hinge/panel materials, such as copper, gold, silver, zinc, Sn, and Ni, were investigated.

In embodiments, such as those provided hereinabove, nickel (Ni) was used to pattern the panels and tin (Sn) was used to pattern the hinges. Again, without wishing to be bound to any one particular theory, it is believed that the Sn/Ni system works well because Sn has intermediate wetting on Ni and Si; thus, the reflowed hinge, which comprises Sn, does not have a strong tendency to spread out of the hinge region of the panel and further onto the Ni or Si surface. Although individual Sn grains could still be observed at these small size scales, grain coalescence and reflow was observed. Further, by controlling both the thickness of the Sn within the hinge and the ratio of CF₄/O₂ gas in the etcher, structures with reproducible 90 degree folds self-assembled. Fold angles less than 90 degrees were observed at low Sn hinge thickness and at very high O₂ partial pressures in the etcher.

Reflow, which refers to liquefaction of a metal, can be challenging to achieve because many metals have a high melting point and also tend to oxidize. Further, in self-assembling structures, the panels need to be released from the substrate simultaneously during reflow to allow them to orient and assemble into the desired 3D structure. In particular embodiments disclosed herein, both steps were achieved in approximately one to two minutes via the presently disclosed reflow process, which, in some embodiments, uses a plasma etcher.

One limitation of surface-tension-based assembly using hinges comprising one or more metals, e.g., tin and/or lead, is the relatively high temperature (e.g., about 188° C. for 60%/40% Sn/Pb solder) that is required to melt the hinges. Such relatively high temperatures can preclude self-assembly in the presence of biological matter and other temperature-sensitive materials when using certain hinge materials. In some embodiments, however, the presently disclosed nanostructures can be metal-free. In such embodiments, the nanostructures can comprise polymeric panels and biodegradable hinges, which can be actuated at lower temperatures (e.g., about 45° C.).

Accordingly, the presently disclosed subject matter provides a method of fabricating a three-dimensional nanostructure comprising a plurality of two-dimensional panels, wherein the two-dimensional panels have at least one face and one edge, wherein at least one edge of two of the plurality of two-dimensional panels are interconnected by one or more hinges, wherein the plurality of two-dimensional panels interconnected by one or more hinges undergo self-assembly to form a hollow, polyhedral shape, and wherein at least one face of one or more of the plurality of two-dimensional panels optionally comprises one or more nanoscale features, the method comprising: (a) patterning a plurality of two-dimensional panels on a substrate, wherein each two-dimensional panel comprising the plurality of two-dimensional panels comprises at least one face and at least one edge; (b) patterning one or more hinges on at least one edge of two or more of the plurality of two-dimensional panels, wherein the one or more hinges interconnect two or more of the plurality of two-dimensional panels; (c) repeating steps (a) and (b) to form one or more two-dimensional precursor templates on the substrate, wherein the two-dimensional precursor template has at least one base two-dimensional panel and at least one two-dimensional side panel, wherein the at least one base two-dimensional panel and at least one two-dimensional side panel are interconnected by at least one hinge; and (d) removing the substrate, thereby causing the one or more two dimensional precursor templates to self-assemble to form a three-dimensional nanostructure. One of ordinary skill in the art would recognize that the panels and hinges can be patterned using conventional lithography processes, including, but not limited to, electron-beam lithography and imprint lithography.

In some embodiments, step (a) above for patterning a plurality of two-dimensional panels on a substrate comprises: (a) depositing a layer of an electron-beam resist on a substrate; (b) curing the electron-beam resist for a period of time; (c) patterning the resist with electron-beam lithography to form a patterned electron-beam resist; (d) developing the patterned electron-beam resist for a period of time to form a developed, patterned electron-beam resist; (e) depositing a layer of a first material on the developed, patterned electron-beam resist; and (f) removing the developed, patterned electron-beam resist to provide a two-dimensional panel comprising the first material on the substrate.

In some embodiments, step (b) above for patterning one or more hinges on at least one edge of two or more of the plurality of two-dimensional panels comprises: (a) depositing a layer of an electron-beam resist on at least one edge of two or more of the plurality of two-dimensional panels; (b) curing the electron-beam resist for a period of time; (c) patterning the resist with electron-beam lithography to form a patterned electron-beam resist; (d) developing the patterned electron-beam resist for a period of time to form a developed, patterned electron-beam resist; (e) depositing a layer of a second material on the developed, patterned electron-beam resist; and (f) removing the developed, patterned electron-beam resist to provide a hinge comprising the second material on at least one edge of two or more of the plurality of two-dimensional panels.

In some embodiments, step (d) above for removing the substrate comprises etching the two-dimensional precursor template on the substrate to remove the substrate. In particular embodiments, the etching removes a portion of the substrate, thereby causing the at least one two-dimensional side panel to self-fold, wherein the at least one base two-dimensional panel remains on the substrate. In additional embodiments, the method comprises further etching the two-dimensional precursor template on the substrate to completely remove the substrate, thereby causing the plurality of two-dimensional panels interconnected by one or more hinges to undergo self-assembly to form a three-dimensional nanostructure.

By using the presently disclosed methods, three-dimensional, complex nanostructures can be fabricated in a highly parallel and efficient process, which allows multiple three-dimensional nanostructures to be formed, i.e., folded, simultaneously. The presently disclosed methods can provide for inexpensive fabrication of patterned nanostructures when implemented with parallel 2D patterning techniques, such as imprint lithography. The parallel nature of the presently disclosed methods is in contrast to two-dimensional processes known in the art, which are serial and, as a result, are time and labor intensive, i.e., they require multiple steps to be performed on each fabricated structure.

Additionally, the presently disclosed self-folding methods can be used to fabricate 3D structures that are patterned in all directions. Such structures can be used as “smart” building blocks in a subsequent self-assembly process to form larger-scale 3D structures with increased complexity. For example, self-folded cubes could be assembled into larger 3D arrays using magnetic forces and hydrophobic/hydrophilic interactions.

Further, due to the flexibility of patterning the 2D net precursor templates, the presently disclosed process is versatile and provides for nanostructures having different sizes and shapes and precise and monodisperse surface porosity. As a result, the presently disclosed 3D nanostructures can be designed such that one or more panels are patterned. In embodiments, the panels can include, for example, an array of nanometer-scale pores, which can be used as 3D membranes for separations and sampling and also have implications for cell encapsulation therapy, as provided herein below. In embodiments comprising nanoscale perforations, such perforations can control the perfusion and release of materials or substances contained within the 3D nano structure to the surrounding medium.

In other embodiments, the presently disclosed nanostructures can be fabricated with materials that interact with electromagnetic fields, which have applications in medical imaging and delivery of therapeutic agents, as also is disclosed herein below. Also, sensors could be designed into the presently disclosed nanostructures by using additional photolithographic steps.

In other embodiments, the presently disclosed nanostructures can be coated with a biocompatible material, including, but not limited to, a metal, a polymer, or a combination thereof.

In summary, the presently disclosed self-assembly process is versatile and provides a method for fabricating both free-standing nanoparticles, as well as those attached to substrates. It is possible to construct nanostructures with any desired nanoscale pattern that can be implemented with conventional lithography processes, including, but not limited to, electron-beam lithography and imprint lithography.

Further, the fold angle between panels can be controlled. Because the orientation angle between panels can be controlled, the presently disclosed methods, in principle, can be used to construct other polyhedral particles in addition to cubic nanoparticles.

Additionally, the presently disclosed particles are stable, and the demonstration of multilayer patterning with dissimilar materials suggests a versatile strategy for the construction of practically applicable, patterned, heterogeneous nanoparticles with different combinations of metals, semiconductors, and insulators. Such patterning could enhance the functionality of the presently disclosed nanostructures for use in electronics, optics, and targeted medicine. Because the presently disclosed particles are patterned, it is anticipated that they will display novel optical properties, such as unique plasmon resonances.

C. Encapsulation and Delivery of Materials and Substances

Further, in some embodiments, the three-dimensional polyhedron formed by self assembly of the plurality of two-dimensional panels is hollow. Accordingly, such structures have a fillable center chamber of nanoscale proportions and can be used as a container, biocontainer, or nanoscale encapsulant. As used herein, the terms “container,” “biocontainer,” and “nanoscale encapsulant” refer to a three-dimensional object, i.e., a receptacle, having a hollow interior or an interior capable of containing substances.

In some embodiments, after self-assembly, the fillable center chamber of the presently disclosed nanostructures is available as a vessel for encapsulation of materials or substances, including, but not limited to, drugs or other therapeutic agents, biological media, including cells and tissues, gels, and polymers, including natural or synthetic polymers, such as proteins (polymer of amino acids) and cellulose (polymer of sugar molecules), which subsequently can be released in situ. See, e.g., U.S. Patent Application Nos. US2007/0020310 A1, published Jan. 25, 2007, and US2009/0311190 A1, published Dec. 17, 2009, each of which is incorporated herein by reference in its entirety.

Accordingly, in some embodiments, the presently disclosed subject matter further provides a method of encapsulating a material or substance in a three-dimensional nanostructure comprising a plurality of two-dimensional panels that self-assemble to form a hollow polyhedral shape and a fillable center chamber, the method comprising: (i) loading the fillable center chamber of the nanostructure with at least one substance to form a loaded nanostructure; and (ii) administering the loaded nanostructure to a subject. In another embodiment, the nanostructure comprises perforations or pores in the two-dimensional panels of the nanostructure, which allow release of the substance in the fillable center chamber. In some embodiments, the at least one substance of step (i) is a therapeutic agent. In some embodiments, the therapeutic agent is selected from the group consisting of a cell, a pharmaceutical agent, a composition, a tissue, a gel, and a polymer.

Such materials or substances can be contained within, loaded into, or otherwise associated with, e.g., directly bound, adhered, or attached through a linker to, the nanostructure. The materials or substances can subsequently be released from the nanostructure. In some embodiments, the release can be a slow or time-elapsed release to provide a pre-determined amount of the material or substance to a subject over a period of time. Such embodiments include both in vitro and in vivo applications. Accordingly, materials or substances encapsulated by the presently disclosed nanostructures can be delivered to a specific target or generally administered to a subject. Thus, in some embodiments, the presently disclosed subject matter further provides a method for targeting a nanostructure to a cell within a subject, the method comprising: (a) attaching to the nanostructure an antibody against an antigen specific to the cell; and (b) administering the nanostructure to the subject, wherein the nanostructure is targeted to the cell.

In some embodiments, the presently disclosed 3D nanostructures can be loaded with cells embedded in a gel. The term “gel” as used herein refers to an apparently solid, jellylike material formed from a colloidal solution. The term “colloid” or “colloidal” as used herein refers to a substance made up of a system of particles dispersed in a continuous medium. By weight, gels are mostly liquid, yet they behave like solids. The term “solution” refers to a homogeneous mixture of one or more substances (the solutes) dissolved in another substance (the solvent). The cells could be released by immersing the nanostructure in an appropriate solvent.

In some embodiments, functional cells (e.g., pancreatic islet cells, neuronal PC12 cells) can be encapsulated for in vitro and in vivo release with or without immunosuppression. For example, the presently disclosed 3D nanostructures can be used to encapsulate and deliver insulin secreting cells for implantation in patients afflicted with diabetes and for placing tumor innocula in animal models where constraining cells within a small region is necessary, and for delivering functional PC12 cells, for example, to model neuronal differentiation.

The presently disclosed subject matter also includes a method of treating a disease, condition, or disorder in a subject in need of treatment thereof, the method comprising administering to the subject at least one nanostructure encapsulating a composition, wherein the composition is released through one or more pores within the nanostructure into the subject in an amount sufficient to treat the condition. In one embodiment of this method the condition is diabetes and the composition comprises one or more insulin-secreting cells.

As used herein, the term “therapeutic agent” refers to any pharmaceutical agent, composition, gene, protein cell, molecule, or substance that can be used to treat, control or prevent a disease, medical condition or disorder. The term “treat” or “treating” includes abrogating, substantially inhibiting, slowing or reversing the progression of a condition, substantially ameliorating clinical or symptoms of a condition, and substantially preventing the appearance of clinical or symptoms of a condition.

The amount of a therapeutic agent that results in a therapeutic or beneficial effect following its administration to a subject, including humans, is a “therapeutic amount” or “pharmaceutically effective amount.” The therapeutic or beneficial effect can be curing, minimizing, preventing, or ameliorating a disease or disorder, or may have any other therapeutic or pharmaceutical beneficial effect.

The term “disease” or “disorder,” as used herein, refers to an impairment of health or a condition of abnormal functioning. The term “syndrome,” as used herein, refers to a pattern of symptoms indicative of some disease or condition. The term “condition,” as used herein, refers to a variety of health states and is meant to include disorders, diseases, or injuries caused by any underlying mechanism or disorder, and includes the promotion of healthy tissues and organs. The term “injury,” as used herein, refers to damage or harm to a structure or function of the body caused by an outside agent or force, which may be physical or chemical.

The subject treated by the presently disclosed methods in their many embodiments is desirably a human subject, although it is to be understood that the methods described herein are effective with respect to all vertebrate species, which are intended to be included in the term “subject.” Accordingly, a “subject” can include a human subject for medical purposes, such as for the treatment of an existing condition or disease or the prophylactic treatment for preventing the onset of a condition or disease, or an animal subject for medical, veterinary purposes, or developmental purposes. Suitable animal subjects include mammals including, but not limited to, primates, e.g., humans, monkeys, apes, and the like; bovines, e.g., cattle, oxen, and the like; ovines, e.g., sheep and the like; caprines, e.g., goats and the like; porcines, e.g., pigs, hogs, and the like; equines, e.g., horses, donkeys, zebras, and the like; felines, including wild and domestic cats; canines, including dogs; lagomorphs, including rabbits, hares, and the like; and rodents, including mice, rats, and the like. In some embodiments, the subject is a human including, but not limited to, fetal, neonatal, infant, juvenile, and adult subjects. Further, a “subject” can include a patient afflicted with or suspected of being afflicted with a condition or disease. Thus, the terms “subject” and “patient” are used interchangeably herein.

D. MRI Imaging

The presently disclosed subject matter further provides a method for imaging a nanostructure that has been introduced into a subject, the method comprising imaging the nanostructure using magnetic resonance imaging. Accordingly, in some embodiments, the presently disclosed nanostructures can be administered to a subject and its location within the subject can be detected and non-invasively tracked using magnetic resonance imaging (MRI) or CAT scan (CT) and do not require the presence of a contrast agent. In some embodiments, the nanostructure can be imaged with negative contrast relative to background or positive contrast relative to background.

The term “magnetic resonance imaging” or “MRI,” refers to a noninvasive imaging technique that uses the interaction between radio frequency pulses, a strong magnetic field, and an subject to construct images in slices/planes from the nuclear magnetic resonance (NMR) signal obtained from the hydrogen atoms inside the subject. The principle behind all MRI is the resonance equation,

ν=γB₀ (Equation 1)

which shows that the resonance frequency ν of a spin is proportional to the magnetic field B₀, it is experiencing, where γ is the gyromagnetic ratio.

Accordingly, in some embodiments, the presently disclosed subject matter further provides a method of imaging a three-dimensional nanostructure comprising a plurality of two-dimensional panels that self-assemble to form a hollow polyhedral shape and a fillable center chamber, the method comprising: (i) loading the fillable center chamber of the nanostructure with at least one substance to form a loaded nanostructure; (ii) administering the loaded nanostructure to a subject; and (iii) noninvasively tracking the nanostructure of step (ii) in the subject by magnetic resonance imaging. In another embodiment, cells within or proximal to targeted nanostructures of the presently disclosed nanostructures can be imaged by MRI to evaluate the efficacy of the implant and the condition of the encapsulated cells.

The presently disclosed subject matter also provides a method for delivering one or more nanostructures to a subject, wherein the one or more nanostructures is programmed to remotely release one or in more reagents at a particular time and a particular spatial location. In one embodiment of this method, the nanostructure is remotely guided and imaged using MRI or CT. Also provided is a method for releasing a contrast agent from the nanostructure or of providing contrast to allow MRI or CT imaging of its contents or of substances within its vicinity.

A method also is provided for conducting a non-invasive biopsy or microsurgery, the method comprising directing one or more nanostructures to a site within a subject using remote means, allowing the nanostructure to capture one or more substances from the site, and obtaining the substance from the particle.

In yet other embodiments, the nanostructures can further comprise a radio frequency tag, wherein the substance may be released upon the nanostructure's exposure to a pre-selected radio frequency. In a further embodiment of the presently disclosed nanostructure, the substance can be released upon the nanostructure's exposure to electromagnetic radiation, which can be triggered remotely. The electromagnetic radiation capable of triggering the release can range from about 1 KHz to about 1 Peta Hz. In a further embodiment, the substance can be released upon the nanostructure's exposure to inductive heating. Such inductive heating can be triggered remotely.

E. Faraday Cage

In one embodiment, the presently disclosed nanostructures can be a Faraday cage. The term “Faraday cage” as used herein refers to an enclosure designed to block the effects of an electric field, while allowing free passage to magnetic fields. (See E. M. Purcell, Electricity and Magnetism, Berkeley Physics Course Volume 2 (McGraw Hill, Mass., 1985)). Such an enclosure also is called a Faraday shield, Faraday shielding, Faraday screen, Faraday electrostatic shield, or shielded room.

In some embodiments, the presently disclosed nanostructures comprise miniature Faraday cages to facilitate detection in MRI. In such embodiments, the nanostructures shield (meaning protect, screen, block, absorb, avoid, or otherwise prevent the effects of) the oscillating magnetic fields that arise from radio frequency (RF) and magnetic field gradients in an imaging sequence. This shielding occurs as a result of eddy currents (meaning circulating currents induced in a conductor moved through a magnetic field, or which is subjected to a varying magnetic field) generated in the frame of the particle that induce a local magnetic field, which interferes destructively with the external magnetic field.

### II. FORMATION OF CURVING NANOSTRUCTURES USING EXTRINSIC STRESS

A. Background

In addition to intrinsic stresses, which build up during the deposition of thin films, stresses also can be induced by external factors post-deposition following growth. These extrinsic stresses can be generated by a variety of mechanisms, such as a temperature change, chemical reactions, magnetic forces, or electric fields. See R. Berger, et al., Science 276:2021 (1997); J. Fritz, et al., Science 288:316 (2000); C. Liu, et al., Sens. Actuators A 78:190 (1999); J. Weissmüller, et al., Science, 300:312 (2003). One advantage of using extrinsic stresses to form curved structures is that the self-assembly can be triggered to occur only when desired. In contrast, multilayer thin films with intrinsic stress assemble spontaneously on release from the substrate. See N. Bassik, G. M. Stern, D. H. Gracias, Appl. Phys. Lett. 295(09):1901 (2009).

B. Formation of Curving Nanostructures Using Extrinsic Stress

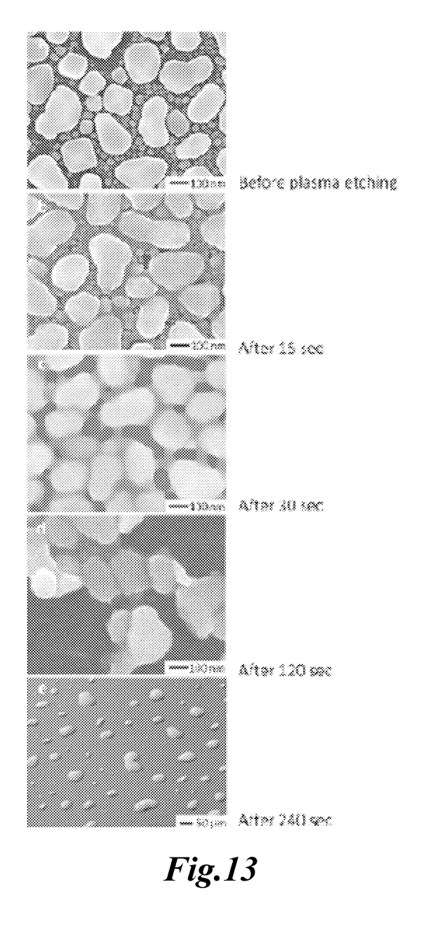

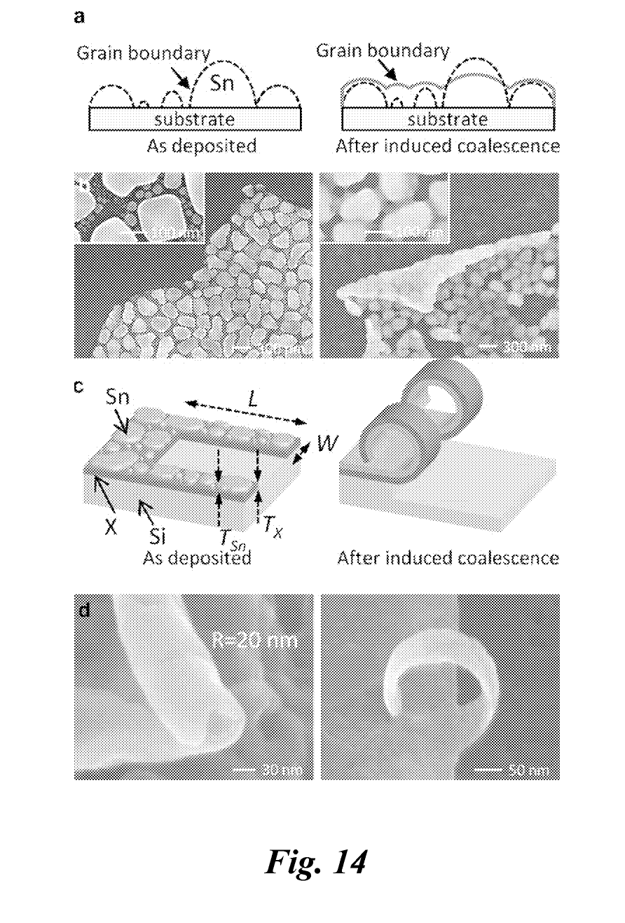

In representative embodiments, after metal deposition, grain coalescence was triggered by plasma etching of the Si substrate with CF₄/O₂; the chemical reactions which occur during etching are exothermic, see J. H. Cho, D. H. Gracias, Nano Lett. 9:4049 (2009); A. N. Magunov, Instrum. Exp. Tech. 43:706 (2000), and the extent of grain coalescence increased with increasing plasma etching times (see FIG. 13, from top panel to bottom panel). This heating induced grain coalescence is accompanied by an increase in the stress within the Sn film (FIG. 14a). Hence, when grain coalescence was induced in Sn films, the edges curled up on release from the underlying Si substrate (see FIG. 14b). Without wishing to be bound to any one particular theory, this curving of Sn films can be rationalized by noting that a stress gradient develops in the coalescing thin film. Because the deposited Sn film was discontinuous (as a result of a Volmer-Weber growth, see S. Hishita, et al., Thin Solid Films. 146:464-465 (2004), however, the radius of curvature at the rolled-up edges was not uniform and was difficult to control reproducibly. Moreover, it was challenging to pattern and create functional nanostructures with these discontinuous, single-layer Sn films.

Accordingly, to use extrinsic stress to curve patterned nanostructures reproducibly, the insertion of a continuous film (denoted as X), in between the Si substrate and the Sn film to form a Si/X/Sn multilayer stack, was investigated (see FIG. 14c). Because the constituent X in the bilayer was continuous, it could be patterned on the nanoscale using e-beam lithography. To retain the induction of grain coalescence observed on bare Si (FIGS. 14a and 14b), it was necessary that the interfacial energy of the material X was such that the deposited Sn film also showed a Volmer-Weber or grain growth (similar to the morphology observed when Sn was deposited on bare Si; (FIGS. 14a and 14b). Then, grain coalescence and the associated extrinsic stress could be induced after deposition and during plasma etching of the underlying Si (FIG. 14c). Nickel (Ni), silica (SiO₂), and alumina (Al₂O₃) satisfy this criterion. E-beam patterned Ni/Sn bilayer films (FIG. 14d) did indeed curve on heating during the exothermic Si etching process. The smallest radii (R=20 nm; FIG. 14d), measured from electron microscopy images, was achieved with a thickness of 5-nm Ni and 5-nm Sn.

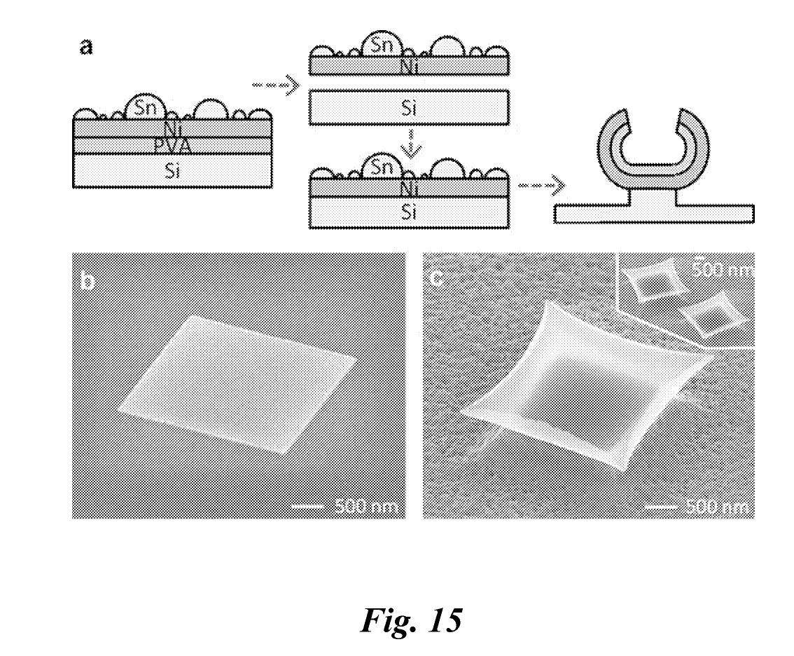

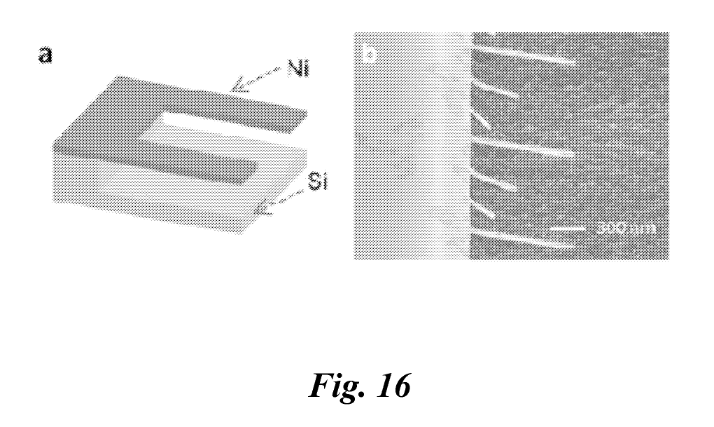

Several control experiments were carried out to confirm that the curving of the bilayers was induced by grain coalescence in the Sn film (FIG. 15 and FIG. 16). The release of the bilayers from the Si substrate and the induced grain coalescence was decoupled by introducing a polymeric (polyvinyl alcohol, PVA) sacrificial release layer between the Si substrate and Ni/Sn patterned bilayers (FIG. 15a). When this PVA layer was dissolved in water, and the patterned Ni/Sn bilayers were released from the underlying substrate, no discernible curvature was observed (FIG. 15b). This experiment indicates that the intrinsic stresses in these metals were not significant enough to curve them.

Subsequently, curvature of these released flat patterned bilayers could be induced by grain coalescence (FIG. 15c), confirming that the extrinsic stresses were responsible for the curvature observed and also that the assembly can be triggered post-deposition, when desired. In the absence of the Sn film, curvature could not be induced in single layer Ni films indicating that no significant extrinsic stresses were generated within these films during plasma etching of Si (see FIG. 16). It also should be noted that these small nanoscale radii cannot arise from the small differences in thermal expansion coefficients of Sn (22.0 μm m⁻¹° C.⁻¹) and Ni (13.4 μm m⁻¹° C.⁻¹). See D. R. Lide, CRC Handbook of Chemistry and Physics, Sec. 12 CRC Press, Boca Raton (2009). Finally, the direction of bilayer curving always was the same and was consistent with the direction that would be expected with a coalescing Sn film atop a relatively neutral stressed Ni film.

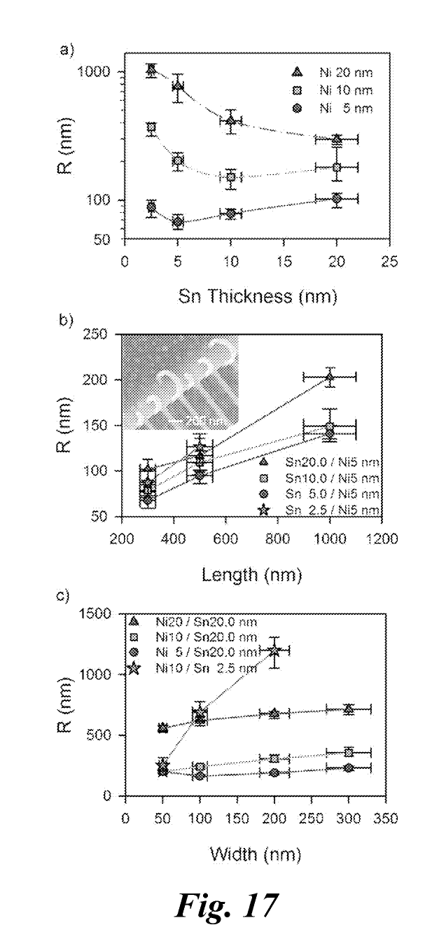

To study the geometric factors affecting curvature, 2D cantilever shaped Ni/Sn bilayers were designed with varying thickness (T), length (L), and width (W) using e-beam lithography and lift-off metallization. The radii of curvature (R) varied considerably when T, L and W were varied (FIG. 17). For the same deposition thickness of Sn, bilayer cantilevers composed of thinner Ni films showed tighter radii of curvature (i.e. smaller R, FIG. 17a [W=50 nm and L=300 nm]). In this cantilever geometry, average R values as low as 70 nm (at a 5-nm Sn and 5-nm Ni thickness) were observed. Longer and wider cantilevers both curved with larger R values (FIGS. 17b and 17c). Although there is no ready explanation for the observed increase in radius with increasing length, this observation was reproducible.

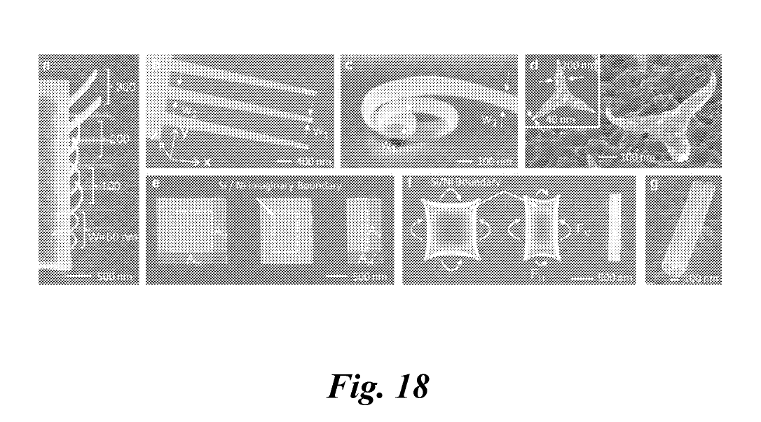

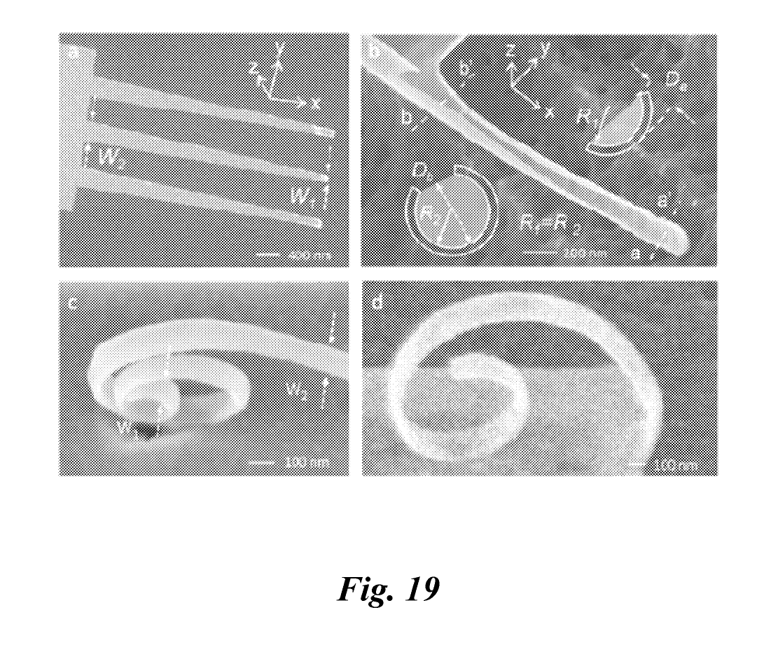

Without wishing to be bound to any one particular theory, the observation of increasing R with increasing W (FIG. 17c and FIG. 18a) can be explained by considering an area moment of inertia (the second moment of area) argument (FIG. 18 and FIG. 19). It is known that the resistance of a beam to bending increases with increasing area moment of inertia. See W. D. Pilkey, Analysis and Design of Elastic Beams, John Wiley & Sons, New York (2002).

Because the beams show simultaneous bending along orthogonal axes, when W is increased, the rolled cross-sectional area (along yz-plane) increases, thus increasing the area moment of inertia in the wider portion of the beam (FIG. 19b). For the same thicknesses of Sn and Ni on cantilevers with varying width, tighter curving (or smaller R values) was observed for the narrower regions. Therefore, by varying the width of the 2D structures, nano structures could be constructed with homogeneous radii of curvature (tubes, rings, and scrolls), as well as those with varying radii (spirals and talons) (FIG. 18). See also, FIG. 19, showing the area moment of inertia vs. R.

The etching geometry of the underlying substrate also can be used to control the structure formed. Square shaped panels curved equally on all four sides, while rectangular shaped panels curved predominantly along the direction of least resistance i.e., along the axis with the smallest area moment of inertia (FIGS. 18e-18g). The shaded region in FIG. 18e refers to the region that will be released from the substrate assuming an isotropic etch rate within the plane.

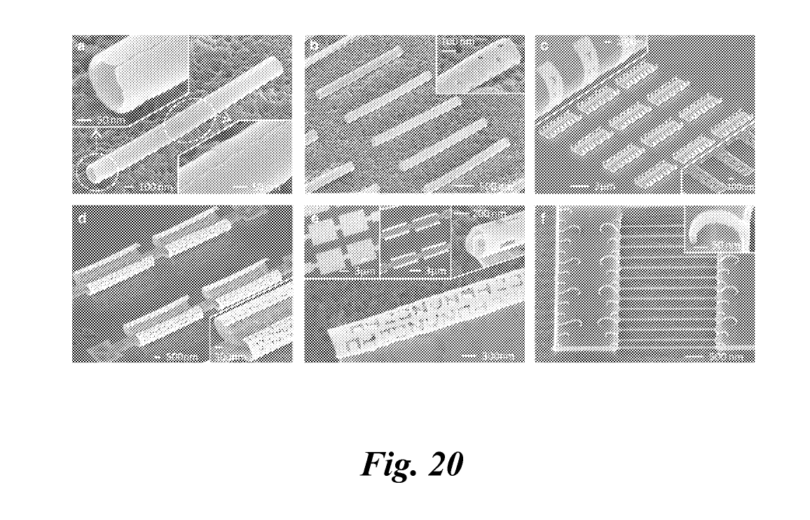

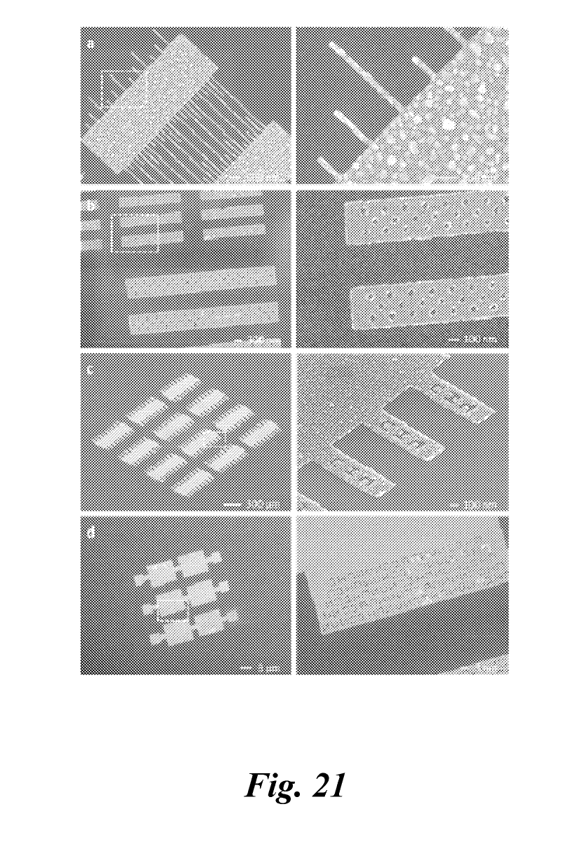

Since the presently disclosed assembly process was compatible with conventional e-beam processing, curved structures could be created with any desired patterns (FIG. 20). Structures were first defined in 2D using e-beam lithography with line widths as small as 20 nm (FIG. 21). To demonstrate patterning versatility, structures with pores and the letters JHU and NANOJHU on them were defined. When grain coalescence was induced, these structures curved spontaneously to form porous nanotubes and lithographically patterned scrolls, rings, and hooks.

Structures composed of Al₂O₃/Sn (FIG. 200 also were created; the viability of curving nanostructures composed of both metallic or dielectric (insulating) materials are important for electronic and photonic applications. See E. J. Smith, et al., Nano Lett. 10:1 (2010). The fact that Al₂O₃/Sn structures curved also supports the proposed mechanism of grain coalescence driving curvature (as opposed to for example Sn/Ni intermetallic formation or other such thermally diffusive or chemically reactive processess between Sn and the underlying film).

The presently disclosed 3D curved and simultaneously patterned structures could have broad utility in optics, electronics, microfluidics, and medicine. Further, since in addition to temperature, extrinsic stresses also can be induced by chemical reactions, adsorption, and electromagnetic fields the presently disclosed processes could be used to create smart nanostructures and materials that can be reconfigured on-demand. The presently disclosed process also is versatile, requires only simple processing steps and is compatible with conventional microelectronic fabrication.

Although specific terms are employed herein, they are used in a generic and descriptive sense only and not for purposes of limitation. Unless otherwise defined, all technical and scientific terms used herein have the same meaning as commonly understood by one of ordinary skill in the art to which this presently described subject matter belongs.

### III. DEFINITIONS

Following long-standing patent law convention, the terms “a,” “an,” and “the” refer to “one or more” when used in this application, including the claims. Thus, for example, reference to “a subject” includes a plurality of subjects, unless the context clearly is to the contrary (e.g., a plurality of subjects), and so forth. The term “plurality” as used herein means “one or more.”

Throughout this specification and the claims, the terms “comprise,” “comprises,” and “comprising” are used in a non-exclusive sense, except where the context requires otherwise. Likewise, the term “include” and its grammatical variants are intended to be non-limiting, such that recitation of items in a list is not to the exclusion of other like items that can be substituted or added to the listed items.

For the purposes of this specification and appended claims, unless otherwise indicated, all numbers expressing amounts, sizes, dimensions, proportions, shapes, formulations, parameters, percentages, parameters, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some embodiments, ±100% in some embodiments±50%, in some embodiments±20%, in some embodiments±10%, in some embodiments±5%, in some embodiments±1%, in some embodiments±0.5%, and in some embodiments±0.1% from the specified amount, as such variations are appropriate to perform the disclosed methods or employ the disclosed compositions.

Further, the term “about” when used in connection with one or more numbers or numerical ranges, should be understood to refer to all such numbers, including all numbers in a range and modifies that range by extending the boundaries above and below the numerical values set forth. The recitation of numerical ranges by endpoints includes all numbers, e.g., whole integers, including fractions thereof, subsumed within that range (for example, the recitation of 1 to 5 includes 1, 2, 3, 4, and 5, as well as fractions thereof, e.g., 1.5, 2.25, 3.75, 4.1, and the like) and any range within that range.

### EXAMPLES

The following Examples have been included to provide guidance to one of ordinary skill in the art for practicing representative embodiments of the presently disclosed subject matter. In light of the present disclosure and the general level of skill in the art, those of skill can appreciate that the following Examples are intended to be exemplary only and that numerous changes, modifications, and alterations can be employed without departing from the scope of the presently disclosed subject matter. The following Examples are offered by way of illustration and not by way of limitation.

### Example 1

### Fabrication Process of Polyhedral Nanoscale Structures

### Fabrication of 2D Nets

On a <100> bare silicon wafer, 50 nm to 100 nm of an electron-beam (e-beam) resist, poly(methylmethacrylate) (PMMA, MW 950K A2) was spun and the wafer was baked at 185° C. for 3 minutes. An e-beam controlled by a RAITH system (Quantum v4.0) was used to pattern the resist. The resist was developed using an MIBK developer (1:3=MIBK: IPA) for 35 seconds. Then, 0.4-nm chromium (Cr) and the desired thickness of Ni were deposited using a thermal evaporator. After evaporation, the resist was dissolved in acetone for lift-off metallization. A second step of e-beam lithography was performed in the same manner and the required thickness of Sn was thermally evaporated.

### Self-assembly of Three-Dimensional Nanostructures

The samples were loaded in a planar etcher (Technics PEII-A) at a base pressure of 0.15 Torr. CF₄ and O₂ were flowed into the etcher for 3 minutes and the 25 W RF power was applied for 40 seconds to 100 seconds. Self-assembly occurred during this time period, after which the power was turned off, and the pressure in the etcher was slowly increased to 1 atm over a period of 5 minutes. In some embodiments, after patterning arrays of the 2D nets, the wafers were introduced into a planar etcher, for example, at 35 kHz, 25 Watts with oxygen (O₂) and carbon tetrafluoride (CF₄) gases.

### Characterization of Reflow Properties of Materials Used to Fabricate Nanostructures

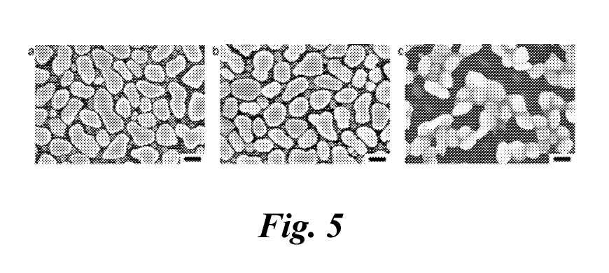

To assess optimum grain size and wetting, a wide range of evaporation parameters and hinge/panel materials, such as copper, gold, silver, zinc, Sn, and Ni, were investigated. A number of gases, such as air, argon (Ar), CF₄, and O₂, were investigated. Unexpectedly, Sn reflowed when exposed to CF₄/O₂ plasma, but did not reflow when exposed to pure O₂, air, or Ar plasma (see FIGS. 5a-5c). Reflow in the absence of CF₄/O₂ was not observed even when the physical etch parameters, such as flow rate, time, and power, were varied.

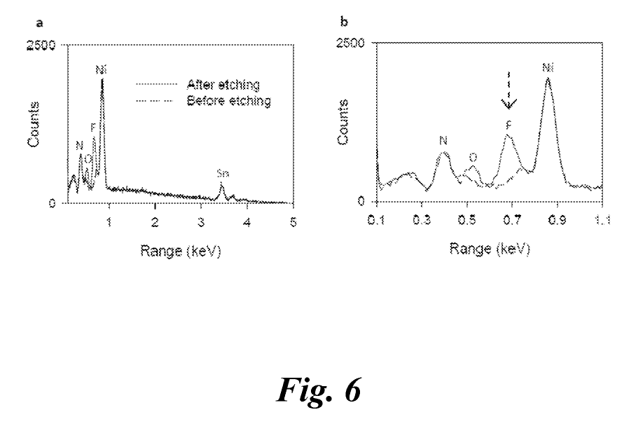

Energy dispersive spectroscopy (EDS) characterization (see FIGS. 6a and 6b) of 50-nm thick Sn films deposited on patterned 10-μm and 200-nm thick square patterns of Ni on Si substrates, before and after etching with the CF₄/O₂ plasma, showed the incorporation of approximately 12% atomic concentration of fluorine (F) after etching. A significant rise in the temperature (over 100° C.) of these thin films deposited on Si substrates also was measured during etching with CF₄/O₂. In contrast, a minimal rise in temperature was observed with the Ar plasma on Sn/Si substrates (approximately 10° C.) or with the CF₄/O₂ plasma on Sn/Al₂O₃ coated Si substrates (approximately 30° C.). These observations indicate that the reaction of the reactive gaseous fluoride species, primarily with Si (but also to some extent with Sn), during plasma etching generates heat, which causes the Sn hinges to reflow. A rise in temperature during the CF₄/O₂ plasma etching of Si has been documented previously. See Magunov, A. N., Instrum. Exp. Tech. 43:133 (2000).

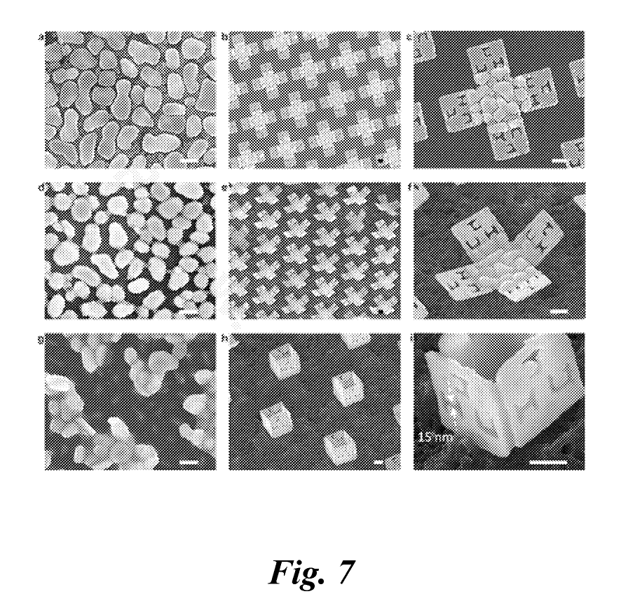

In some embodiments, the angular orientation between panels could be controlled by altering the flow rate of O₂ gas during etching. The dependence of angular orientation on the assembly of 500-nm nets is illustrated in FIGS. 7a-71. On the 500-nm cubic particles, the central panel was unpatterned, whereas the other four panels had the letters JHU patterned on them (see FIGS. 7b and 7c). In these embodiments, the flow rate of CF₄ was kept constant at 12 sccm. At low O₂ flow rates, e.g., approximately 0.2 sccm, some grain coalescence (of grains less than 50 nm in size) was observed, but no significant reflow of large grains was observed (FIG. 7d). At these flow rates approximately 45° angles were observed (see FIGS. 7e and 7f). A higher O₂ flow rate, e.g., approximately 3.6 sccm, resulted in grain coalescence, reflow of large grains (FIG. 7g) and 90° angles (see FIGS. 7h and 7i).

Without wishing to be bound to any one particular theory, it is believed that this observation can by rationalized by noting that the observed amount of O₂ needs to be added to CF₄ to increase the concentration of reactive fluorine atoms. See Mogab, C. J., et al., J. Appl. Phys. 49:3796 (1978). These reactive fluorine atoms are essential for both etching and reflow, and hence self-assembly. Large O₂ concentrations, however, can oxidize Sn and inhibit reflow, because the melting point of tin oxide (SnO) is much higher than that of Sn. See Lide, D. R., in Handbook of CRC Handbook of Chemistry and Physics (CRC Press, 2003).

In other representative embodiments, 500-nm cubic particles were patterned with curvilinear features having line widths as small as 15 nm (see FIG. 7i).

### Example 2

### Representative Polyhedral Nanostructures

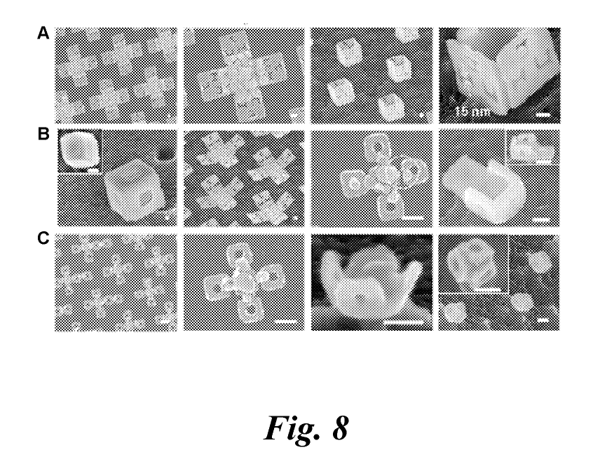

Referring now to FIG. 8A, scanning electron microscopy (SEM) images of the representative 2D templates and the resulting 3D nanostructures are shown. The first panel of FIG. 8A shows a plurality of two-dimensional (2D) templates having a plurality of panels and a plurality hinges prepared by using the presently disclosed two-step electron-beam (e-beam) lithography method. Moving from left to right of FIG. 8A, the next panel shows a magnified SEM image of a 500-nm sized 2D precursor template. Again moving from left to right of FIG. 8A, the next panel shows self assembly of a plurality of precursor templates into cubic nanostructures having a base panel and four side panels. The next panel to the extreme right of FIG. 8A shows a magnified SEM image of a presently disclosed cubic nanostructure having the letters “JHU” patterned on the face of each side panel. In this particular example, the line width of the JHU pattern is about 15 nm.

Referring now to FIG. 8B, a series of SEM images of representative nanostructures is shown. The first panel of FIG. 8B shows SEM images of correctly assembled 200-nm and 900-nm sized cubes with a square patterned on the face of each panel. Moving from left to right of FIG. 8B, precursor templates having a fold angle of less than about 90 degrees are shown. Such precursor templates were observed at very low or high O₂ gas partial pressure. Moving again from left to right of FIG. 8B, the next panel shows a precursor template having a defect in e-beam lithographic alignment registry, which resulted in a missing and/or discontinuous hinge. As shown in the next panel to the extreme right of FIG. 8B, this defect prevented the respective panel from rotating and completing the cube structure. Nevertheless, the presently disclosed process was reproducible down to the 100-nm length scale. See, for example, FIG. 8C.

Referring now to FIG. 8C, SEM images of representative precursor templates having 100-nm sized panels are shown. The first panel of FIG. 8C shows a plurality of two-dimensional (2D) precursor templates having a circle patterned on the face of each panel. Moving from left to right of FIG. 8C, the next panel shows a magnified SEM image of a 100-nm sized 2D template. Again moving from left to right of FIG. 8C, the next panel shows self assembly of the precursor templates into a cubic nanostructure with a hinge angle of less than 90 degrees. The next panel of FIG. 8C shows a cubic nanostructure having 90-degree fold angles.

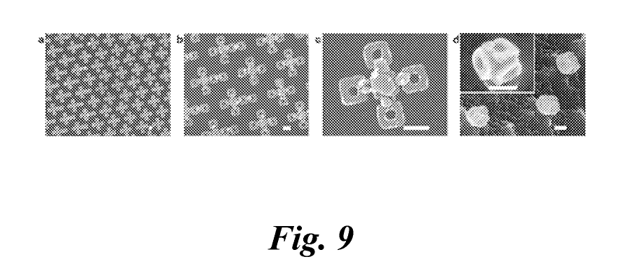

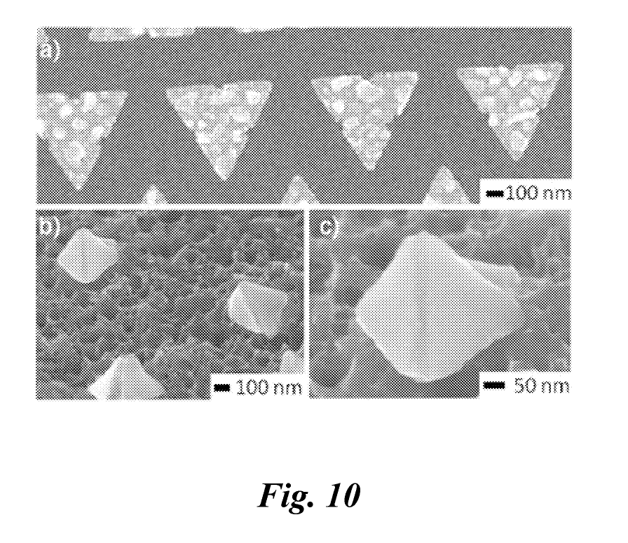

Referring now to FIGS. 9a-9d, EBL patterned 2D nets and resulting self-assembled cubic nanoparticles with overall dimensions of 100 nm are shown. The 100-nm cubes had square patterns with a 30-nm length, the thickness of the panels was 13 nm, and the gap between panels was approximately 10 nm (see FIG. 9a). In some embodiments, the presently disclosed nanoparticles, e.g., the 100-nm nanoparticles illustrated in FIG. 9, are magnetic and hollow and have attoliter encapsulation volumes. These particles assembled while being attached to the substrate (see FIG. 9d), and could be released completely from the substrate by prolonged etching.

### Example 3

### Fabrication of 2D Nets with Gold Patterns

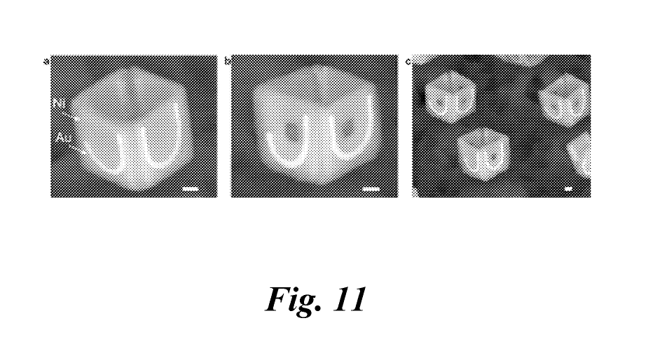

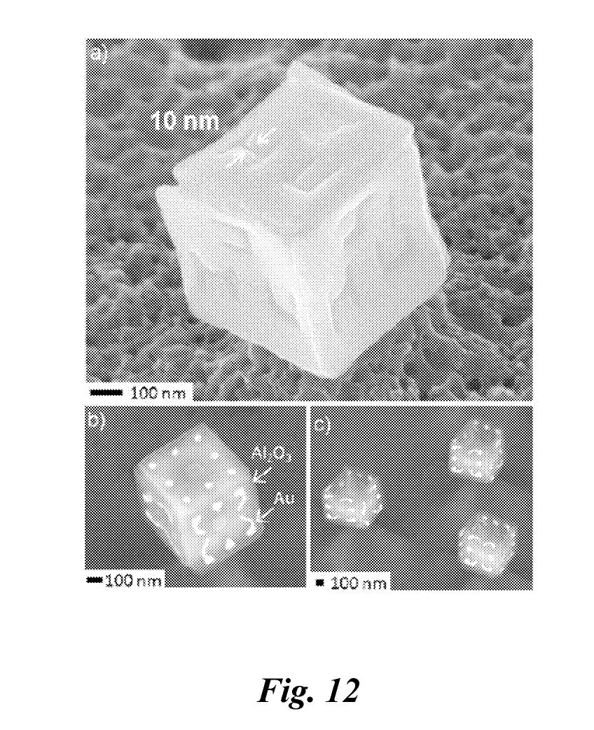

Further, the presently disclosed assembly process can be used with patterned, multilayer panels comprising dissimilar materials. For example, self-assembly of panels with curvilinear patterns of gold (Au) on Ni resulted in cubic nanoparticles with Au patterns (the letters J and U with 50 nm line widths) incorporated on the outer faces (see FIG. 11). This process required three steps of e-beam lithography. On a silicon wafer, 5 nm thick Cr and 20 nm thick gold (Au) were patterned first using e-beam lithography and liftoff metallization. On top of the Au patterns, panels with 34 nm thick Ni and 54 nm thick Sn hinges were patterned. See also, FIG. 12, which provides SEM images of five- and six-faced cubes with patterns, including metallic six-faced cubes with JHU inscribed on each face; and alumina (Al₂O₃) cubes with gold patterns on each face.

### Example 4

### Formation of Curving Nanostructures Using Extrinsic Stress

### Fabrication of 2D Patterns on a Silicon Wafer

On an n-type <100> bare silicon wafer, 100 nm of an electron-beam (e-beam) resist, polymethylmethacraylate (PMMA, MW 950K 2A) was spun and the wafer was baked at 185° C. for 3 min. An electron beam controlled by a RAITH system (v 4.0) was used to pattern the resist. The resist was developed using an MIBK developer (1 to 3 parts IPA) for 35 s. Then, 0.2-nm chromium (Cr) and the respective thickness of Ni or Al₂O₃ were deposited using a thermal evaporator (for Ni) or an electron beam evaporator (for Al₂O₃). On the top of the sample, the required thickness of Sn was thermally evaporated. After evaporation, the resist was dissolved in acetone for lift-off metallization.

### Fabrication of 2D Patterns on PVA

This process required inserting a PVA sacrificial layer between the silicon wafer and PMMA. On an n-type <100> bare silicon wafer, 500 nm thick PVA was spun and the wafer was baked at 115° C. for 12 h. On top of the PVA layer, PMMA was spun and baked. After e-beam lithography and metal deposition, the sample was dissolved in acetone for lift-off metallization. Acetone dissolved the e-beam resist; however, it does not attack PVA, because PVA is a water-soluble polymer. To dissolve PVA, the samples were rinsed a couple of times in deionized water.

### Induction of Grain Coalescence

The samples were loaded in a planar etcher (Technics PEII-A) at a base pressure of 0.15 Torr. Carbon tetrafluoride (CF₄) and oxygen (O₂) were flowed into the etcher for 3 min and 25 W RF power was applied for 3 min. Significant grain coalescence occurred during this time period, after which the power was turned off, and the pressure in the etcher was slowly increased to 1 atm over a period of 5 min.

### REFERENCES

All publications, patent applications, patents, and other references mentioned in the specification are indicative of the level of those skilled in the art to which the presently disclosed subject matter pertains. All publications, patent applications, patents, and other references are herein incorporated by reference to the same extent as if each individual publication, patent application, patent, and other reference was specifically and individually indicated to be incorporated by reference. It will be understood that, although a number of patent applications, patents, and other references are referred to herein, such reference does not constitute an admission that any of these documents forms part of the common general knowledge in the art.
Qin, L.; Park, S.; Huang, L.; Mirkin, C. Science 2005, 309, 113;
Zhang, Z.; Glotzer, S. C. Nano Lett. 2004, 4, 1407;
Jackson, A. M.; Myerson, J. W.; Stellacci, F. Nat. Mater. 2004, 3, 330;
Srinivas, G.; Pitera, J. W. Nano Lett. 2008, 8, 611;
Gleiche, M.; Chi, L. F.; Fuchs, H. Nature 2000, 403, 173;
Curtis, A. S. G.; Casey, B.; Gallagher, J. O.; Pasqui, D.; Wood, M. A.; Wilkinson, C. D. Biophys. Chem. 2001, 94, 275;
Turner, S.; Kam, L.; Isaacson, M.; Craighead, H. G.; Shain, W.; Turner, J. J. Vac. Sci. Technol., B 1997, 15, 2848;
Rastegar, A.; Skarabot, M.; Blij, B.; Rasing, T. J. Appl. Phys. 2001, 89, 960;
Gay, G.; Alloschery, 0; Viaris de Lesegno, B.; O'Dwyer, C.; Weiner, J.; Lezec, H. J. Nat. Phys. 2006, 2, 262;
Grzybowski, B.; Whitesides, G. M. Science 2002, 295, 2418;
Beaumont, S. P.; Bower, P. G.; Tamamura, T.; Wilkinson, C. D. W. Appl. Phys. Lett. 1981, 38, 436;
Chou, S. Y.; Krauss, P. R.; Renstrom, P. J. Science 1996, 272, 85;
Liu, G.-Y.; Xu, S.; Qian, Y. Acc. Chem. Res. 2000, 33, 457;
Terfort, A.; Bowden, N.; Whitesides, G. M. Nature 1997, 386, 162;
Gracias, D. H.; Tien, J.; Breen, T. L.; Hsu, C.; Whitesides, G. M. Science 2000, 289, 1170;
Syms, R. R. A.; Yeatman, E. M.; Bright, V. M.; Whitesides, G. M. J. Microelectromech. Syst. 2003, 12, 387;
Leong, T. G.; Lester, P. A.; Koh, T. L.; Call, E. K.; Gracias, D. H. Langmuir 2007, 23, 8747;
Magunov, A. N. Instrum. Exp. Tech. 2000, 43, 133;
Mogab, C. J.; Adams, A. C.; Flamm, D. L. J. Appl. Phys. 1978, 49, 3796;
He, Y.; Ye, T.; Su, M.; Zhang, C.; Ribbe, A. E.; Jiang, W.; Mao, C Nature 2008, 452, 198;
Lide, D. R., in Handbook of CRC Handbook of Chemistry and Physics (CRC Press, 2003).
G. G. Stoney, Pro. R. Soc. London A 1909, 82, 172.
W. D. Nix, Metall. Mater. Trans. A 1989, 20, 2217.
L. B. Freund, S. Suresh, Thin Film Materials: Stress, Defect Formation and Surface Evolution; Cambridge University Press, New York, 2009.
R. Koch, J. Phys. Condens. Matter 1994, 6, 9519.
R. W. Hoffman, Thin Solid Films 1976, 34, 185.
M. Ohring, Materials Science of Thin Films, Academic Press, San Diego, 2002, pp. 711-781.
C. L. Chua, D. K. Fork, K. V. Schuylenbergh, J. P. Lu, J. Microelectromech. Syst. 2003, 12, 989.
Y. V. Nastaushev, V. Y. Prinz, S, N. Svitasheva, Nanotechnology 2005, 16, 908.
O. G. Schmidt, N. Schmarje, C. Deneke, C. MUller, N.-Y. Jin-Phillipp, Adv. Mater. 2001, 13, 756.
M. Huang, C. Boone, M. Roberts, D. E. Savage, M. G. Lagally, N. Shaji, H. Qin, R. Blick, J. A. Nairn, F. Liu, Adv. Mater. 2005, 17, 2860.
V. Y. Prinz, V. A. Seleznev, A. K. Gutakovsky, A. V. Chehovskiy, V. V. Preobrazhenskii, M. A. Putyato, T. A. Gavrilova, Physica E 2000, 6, 828.
O. G. Schmidt, K. Eberl, Nature 2001, 410, 168.
Y. Mei, D. J. Thurmer, C. Deneke, S. Kiravittaya, Y. F. Chen, A. Dadgar, F. Bertram, B. Bastek, A. Krost, J. Christen, T. Reindl, M. Stoffel, E. Coric, O. G. Schmidt, ACS Nano 2009, 3, 1663.
R. Berger, E. Delamarche, H. P. Lang, C. Gerber, J. K. Gimzewski, E. Meyer, H.-J. Güntherodt, Science 1997, 276, 2021.
J. Fritz, M. K. Baller, H. P. Lang, H. Rothuizen, P. Vettiger, E. Meyer, H.-J. aintherodt, Ch. Gerber, J. K. Gimzewski, Science 2000, 288, 316.
C. Liu, T. Tsao, G.-B. Lee, J. T. S. Leu, Y. W. Yi, Y.-C. Tai, C.-M. Ho, Sens. Actuators A 1999, 78, 190.
J. Weissmüller, R. N. Viswanath, D. Kramer, P. Zimmer, R. Würschum, H. Gleiter, Science 2003, 300, 312.
N. Bassik, G. M. Stern, D. H. Gracias, Appl. Phys. Lett. 2009, 95(09), 1901.
J. H. Cho, D. H. Gracias, Nano Lett. 2009, 9, 4049.
A. N. Magunov, Instrum. Exp. Tech. 2000, 43, 706.
S. Hishita, Z. Stryhal, I. Sakaguchi, N. Ohashi, N. Saito, H. Haneda, Thin Solid Films. 2004, 464-465, 146.
D. R. Lide, CRC Handbook of Chemistry and Physics, Sec. 12 CRC Press, Boca Raton, 2009.
W. D. Pilkey, Analysis and Design of Elastic Beams, John Wiley & Sons, New York, 2002.
E. J. Smith, Z. Liu, Y. Mei, O. G. Schmidt, Nano Lett. 2010, 10, 1.

Although the foregoing subject matter has been described in some detail by way of illustration and example for purposes of clarity of understanding, it will be understood by those skilled in the art that certain changes and modifications can be practiced within the scope of the appended claims.

That which is claimed:

1. A three-dimensional nanostructure comprising a plurality of two-dimensional panels, wherein the two-dimensional panels have at least one face and one edge, wherein at least one edge of two of the plurality of two-dimensional panels are interconnected by one or more hinges, wherein the plurality of two-dimensional panels interconnected by one or more hinges undergo self-assembly to form a hollow, polyhedral shape, and wherein at least one face of one or more of the plurality of two-dimensional panels optionally comprises one or more nanoscale features.

2. The three-dimensional nanostructure of claim 1, wherein the plurality of two-dimensional panels comprise at least one material selected from the group consisting of a metal, a polymer, a glass, a semiconductor, an insulator, a dielectric, and combinations thereof.

3. The three-dimensional nanostructure of claim 2, wherein the metal is selected from the group consisting of nickel, tin, copper, gold, silver, and zinc.

4. The three-dimensional nanostructure of claim 3, wherein the metal comprises nickel.

5. The three-dimensional nanostructure of claim 1, wherein the one or more hinges comprise at least one liquefiable or coalescing material selected from the group consisting of a metal, a solder, a metallic, a polymer, and a glass.

6. The three-dimensional nanostructure of claim 5, wherein the metal comprises tin.

7. The three-dimensional nanostructure of claim 1, wherein the polyhedral shape is selected from the group consisting of a cube and a pyramid.

8. The three-dimensional nanostructure of claim 1, wherein the nanostructure has a dimension ranging from about 100 nm to about 900 nm.

9. The three-dimensional nanostructure of claim 1, wherein the one or more nanoscale feature comprises a curvilinear pattern.

10. The three-dimensional nanostructure of claim 9, wherein the curvilinear pattern has a width ranging from about 0.1 nm to about 50 nm.

11. The three-dimensional nanostructure of claim 1, wherein the plurality of two-dimensional panels further comprise one or more pores or perforations.

12. The three-dimensional nanostructure of claim 11, wherein the one or more pores or perforations have a geometric shape selected from the group consisting of a circle and a square.

13. The method of claim 1, wherein the one or more nanoscale features comprise an element of an electronic circuit or a complete electronic circuit.

14. The method of claim 13, wherein the element of an electronic circuit or a complete electronic circuit is selected from the group consisting of a photovoltaic, an electrode element, a semiconductor component, a transistor, a diode, a photodiode, a sensor, an actuator, and a solar cell.

15. The method of claim 1, wherein the one or more nanoscale features comprise a biomolecule.

16. The method of claim 15, wherein the biomolecule is selected from the group consisting of a protein, DNA, and a small organic molecule.

17. The method of claim 15, wherein the one or more nanoscale features comprise an optical element.

18. The method of claim 17, wherein the optical element is selected from the group consisting of a split ring resonator, a light emitting device, a lasing device, a mirror, and a wave guiding device.

19. A method of fabricating a three-dimensional nanostructure comprising a plurality of two-dimensional panels, wherein the two-dimensional panels have at least one face and one edge, wherein at least one edge of two of the plurality of two-dimensional panels are interconnected by one or more hinges, wherein the plurality of two-dimensional panels interconnected by one or more hinges undergo self-assembly to form a hollow, polyhedral shape, and wherein at least one face of one or more of the plurality of two-dimensional panels optionally comprises one or more nanoscale features, the method comprising:
(a) patterning a plurality of two-dimensional panels on a substrate, wherein each two-dimensional panel comprising the plurality of two-dimensional panels comprises at least one face and at least one edge;
(b) patterning one or more hinges on at least one edge of two or more of the plurality of two-dimensional panels, wherein the one or more hinges interconnect two or more of the plurality of two-dimensional panels;
(c) repeating steps (a) and (b) to form one or more two-dimensional precursor templates on the substrate, wherein the two-dimensional precursor template has at least one base two-dimensional panel and at least one two-dimensional side panel, wherein the at least one base two-dimensional panel and at least one two-dimensional side panel are interconnected by at least one hinge; and
(d) removing the substrate, thereby causing the one or more two-dimensional precursor templates to self-assemble to form a three-dimensional nanostructure.

20. The method of claim 19, wherein the patterning of the plurality of two-dimensional panels and the patterning of the one or more hinges comprises a lithography process.

21. The method of claim 20, wherein the lithography process is selected from the group consisting of electron-beam lithography and imprint lithography.

22. The method of claim 19, wherein step (a) for patterning a plurality of two-dimensional panels on a substrate comprises:
(a) depositing a layer of an electron-beam resist on a substrate;
(b) curing the electron-beam resist for a period of time;
(c) patterning the resist with electron-beam lithography to form a patterned electron-beam resist;
(d) developing the patterned electron-beam resist for a period of time to form a developed, patterned electron-beam resist;
(e) depositing a layer of a first material on the developed, patterned electron-beam resist; and
(f) removing the developed, patterned electron-beam resist to provide a two-dimensional panel comprising the first material on the substrate.

23. The method of claim 19, wherein step (b) for patterning one or more hinges on at least one edge of two or more of the plurality of two-dimensional panels comprises:
(a) depositing a layer of an electron-beam resist on at least one edge of two or more of the plurality of two-dimensional panels;
(b) curing the electron-beam resist for a period of time;
(c) patterning the resist with electron-beam lithography to form a patterned electron-beam resist;
(d) developing the patterned electron-beam resist for a period of time to form a developed, patterned electron-beam resist;
(e) depositing a layer of a second material on the developed, patterned electron-beam resist; and
(f) removing the developed, patterned electron-beam resist to provide a hinge comprising the second material on at least one edge of two or more of the plurality of two-dimensional panels.

24. The method of claim 19, wherein step (d) for removing the substrate comprises etching the two-dimensional precursor template on the substrate to remove the substrate, wherein the etching comprises plasma etching or wet chemical etching.

25. The method of claim 24, wherein the etching removes a portion of the substrate, thereby causing the at least one two-dimensional side panel to self-fold, wherein the at least one base two-dimensional panel remains on the substrate.

26. The method of claim 25, comprising further etching the two-dimensional precursor template on the substrate to completely remove the substrate, thereby causing the plurality of two-dimensional panels interconnected by one or more hinges to undergo self-assembly to form a three-dimensional nanostructure.

27. The method of claim 19, wherein the substrate is a silicon wafer.

28. The method of claim 22, wherein the electron-beam resist is poly(methylmethacrylate).

29. The method of claim 22, wherein the curing of the electron-beam resist comprises heating the substrate having the electron-beam resist deposited thereon at about 185° C.

30. The method of claim 22, wherein the patterned electron-beam resist is developed with methyl isobutyl ketone (MIBK).

31. The method of claim 22, wherein the first material comprises nickel (Ni).

32. The method of claim 23, wherein the second material comprise tin (Sn).

33. The method of claim 19, further comprising patterning the plurality of two-dimensional panels to include one or more pores or perforations.

34. The method of claim 19, further comprising patterning the plurality of two-dimensional panels to include one or more nanoscale features.

35. The method of claim 34, comprising patterning the plurality of two-dimensional panels with one or more nanoscale features using lift-off metallization.

36. The method of claim 35, comprising patterning the plurality of two-dimensional panels with one or more nanoscale features having a curvilinear shape.

37. The method of claim 36, wherein the curvilinear shape comprises a line having a length, a height, and a width.

38. The method of claim 37, wherein the width has a dimension ranging from about 10 nm to about 50 nm.

39. The method of claim 34, wherein the one or more nanoscale features comprises gold.

40. A three-dimensional nanostructure prepared by the method of claim 19.

41. A method for forming a curved nanostructure, the method comprising:
(a) patterning a layer of a first material on a substrate;
(b) depositing a layer of a second material on the layer of the first material to form a multilayer structure comprising the substrate/first material/second material;
(c) removing the substrate to form a bilayer structure comprising the first material/second material; and
(d) inducing grain coalescence in the second material to form a curved nanostructure.

42. The method of claim 41, wherein step(a) comprises:
(a) depositing a layer of an electron-beam photoresist on a substrate;
(b) patterning the layer of electron-beam photoresist using electron-beam lithography to form a patterned layer of electron-beam photoresist;
(c) developing the patterned electron-beam photoresist to form a developed, patterned electron-beam photoresist; and
(d) depositing a layer of a first material on the developed, patterned electron-beam photoresist to form a patterned layer of a first material on a substrate.

43. The method of claim 42, wherein the electron-beam photoresist comprises polymethylmethacrylate (PMMA).

44. The method of claim 43, wherein the patterned electron-beam photoresist is developed with an MIBK developer.

45. The method of claim 43, wherein the depositing of the first material in step (d) comprises thermal evaporation or electron-beam evaporation.

46. The method of claim 41, wherein the substrate comprises a silicon wafer.

47. The method of claim 41, wherein the first material is selected from the group consisting of Ni, Al₂O₃, and SiO₂.

48. The method of claim 41, wherein the first material has a thickness ranging from about 1 nm to about 30 nm.

49. The method of claim 41, wherein the second material is tin.

50. The method of claim 41, wherein the second material has a thickness ranging from about 1 nm to about 30 nm.

51. The method of claim 41, wherein the depositing of the second material in step (b) comprises thermal evaporation.

52. The method of claim 41, wherein the removing of the developed, patterned electron-beam photoresist of step(c) comprises dissolving the photoresist in a solvent by a lift-off metallization process.

53. The method of claim 41, wherein the inducing of grain coalescence of the second material to form a curved nanostructure comprises etching.

54. The method of claim 53, wherein the etching is selected from the group consisting of plasma etching and wet chemical etching.

55. The method of claim 53, wherein the etching comprising etching the second material in a planar etcher.

56. The method of claim 54, wherein the plasma etching comprises etching the second material in the presence of carbon tetrafluoride (CF₄) and oxygen (O₂).

57. The method of claim 41, wherein the curved nanostructure has a radius of curvature ranging from about 10 nm to about 500 nm.

58. The method of claim 41, wherein the curved nanostructure has a length ranging from about 100 nm to about 1000 nm.

59. The method of claim 41, wherein the curved nanostructure has a width ranging from about 25 nm to about 500 nm.

60. A curved nanostructure fabricated by the method of claim 41.
